(19) United States
(12) Patent Application Publication
(10) Pub. No.: US 2025/0290709 A1
(43) Pub. Date: Sep. 18, 2025

(54) MONITORING DEVICE, CONTROL DEVICE, OPERATION MANAGEMENT SYSTEM, AND MEDIUM

(71) Applicant: DENSO CORPORATION, Kariya-city (JP)

(72) Inventors: Yuji YAMAGAMI, Kariya-city (JP); Masaya NAKAMURA, Kariya-city (JP); Shuhei YOSHIDA, Kariya-city (JP); Hisashi UMEMOTO, Kariya-city (JP)

(21) Appl. No.: 19/221,035

(22) Filed: May 28, 2025

Related U.S. Application Data
(63) Continuation of application No. PCT/JP2023/040145, filed on Nov. 8, 2023.

(30) Foreign Application Priority Data
Dec. 7, 2022 (JP) 2022-195906

(51) Int. Cl. F28D 20/02; B64D 27/357; B64D 31/16; B64F 5/60; F28D 21/00; G01R 31/382; G05D 1/85; G05D 1/86; G05D 109/22

(52) U.S. Cl. CPC F28D 20/028; B64D 27/357; B64D 31/16; B64F 5/60; G01R 31/382; G05D 1/85; G05D 1/86; F28D 2021/0021; G05D 2109/23

(57) ABSTRACT

A monitoring device monitors a state of a battery pack mounted on an eVTOL. The monitoring device includes: an acquisition unit configured to acquire information regarding the battery pack; an estimation unit configured to estimate a phase state of a latent heat storage material based on the acquired information; and an output unit configured to output information regarding the phase state. By using the monitoring device, a performance of the latent heat storage material required for cooling a battery can be obtained. Thus, flight safety can be effectively improved.

### CROSS REFERENCE TO RELATED APPLICATION

The present application is a continuation application of International Patent Application No. PCT/JP2023/040145 filed on Nov. 8, 2023, which designated the U.S. and claims the benefit of priority from Japanese Patent Application No. 2022-195906 filed on Dec. 7, 2022. The entire disclosures of all of the above applications are incorporated herein by reference.

### TECHNICAL FIELD

The disclosure of the present application relates to a monitoring device, a control device and a control method, an operation management system, and a non-transitory computer readable medium storing a computer program product.

### BACKGROUND

A relevant art discloses a battery pack installed in an electric flying object. The battery pack includes a battery and a latent heat storage material.

### SUMMARY

According to an aspect of the present disclosure, a monitoring device is for monitoring a state of a battery pack mounted on an electric flying object. The battery pack includes a battery and a latent heat storage material that is capable of changing a phase state between a solid and a liquid. In this case, the monitoring device may include: an acquisition unit configured to acquire information regarding the battery pack; an estimation unit configured to estimate the phase state of the latent heat storage material based on the acquired information; and an output unit configured to output information regarding the phase state.

According to another aspect of the present disclosure, a control device for an electric flying object may include: an acquisition unit configured to acquire information regarding a phase state of a latent heat storage material; and a control unit configured to control an output of the battery based on the phase state.

According to another aspect of the present disclosure, an operation management system may include: a monitoring device configured to acquire information regarding a battery pack that is mounted on an electric flying object and to estimate a phase state of a latent heat storage material that is provided in the battery pack; and a control device configured to control an output of a battery provided in the battery pack, based on the phase state of the latent heat storage material.

According to another aspect of the present disclosure, a non-transitory computer readable medium storing a computer program product may include instructions configured to, when executed by at least one processor, cause the at least one processor to acquire information regarding a battery pack, and to estimate a phase state of a latent heat storage material of the battery pack based on the acquired information regarding the battery pack. For example, the non-transitory computer readable medium may be configured to control an output of a battery in the battery pack based on the estimated phase state.

According to another aspect of the present disclosure, a computer-implemented method performed by at least one processor, is for controlling an electric flying object that drives a drive target including a rotor by using a battery pack, and include: acquiring information regarding a phase state of a latent heat storage material provided in the battery pack, and controlling an output of a battery in the battery pack based on the phase state.

### BRIEF DESCRIPTION OF THE DRAWINGS

Objects, features, and advantages of the present disclosure will become more apparent from the following detailed description made with reference to the accompanying drawings, in which:

FIG. 1 is a diagram showing a power profile of an eVTOL;

FIG. 2 is a diagram showing a configuration of the eVTOL and a ground station;

FIG. 3 is a perspective view showing a schematic configuration of a battery pack;

FIG. 4 is a side view of FIG. 3 as viewed in a Y1 direction;

FIG. 5 is a diagram showing a functional arrangement of an operation management system according to a first embodiment;

FIG. 6 is a diagram showing a schematic configuration of a monitoring device and the operation management system;

FIG. 7 is a flowchart showing an example of a monitoring method;

FIG. 8 is a flowchart illustrating another example of the monitoring method;

FIG. 9 is a diagram showing a schematic configuration of a monitoring device and an operation management system according to a modification;

FIG. 10 is a flowchart showing a pre-flight processing according to a modification;

FIG. 11 is a flowchart showing a pre-flight processing according to a modification;

FIG. 12 is a flowchart showing a during-flight processing according to a modification;

FIG. 13 is a diagram showing changes in battery temperature during flight;

FIG. 14 is a diagram showing a schematic configuration of a control device and an operation management system according to a second embodiment;

FIG. 15 is a flowchart showing an example of a control method;

FIG. 16 is a flowchart showing an air-conditioning control;

FIG. 17 is a flowchart showing a propellant landing control;

FIG. 18 is a flowchart showing a pre-flight control according to a modification; and

FIG. 19 is a flowchart showing a pre-flight control according to another modification.

### DESCRIPTION OF EMBODIMENTS

A battery pack installed in an electric flying object includes a battery and a latent heat storage material, as disclosed in US 2022/0285762A1 which is incorporated herein by reference as an explanation of technical elements in the present disclosure. When the battery pack is removed from the electric flying object and the battery is charged, the battery pack is connected to a cooling device in which a refrigerant flows. In such manner, the latent heat storage material changes its state from a liquid phase to a solid phase.

However, the batteries of the electric flying object are required to provide high output continuously for a certain period of time during both of takeoff and landing. Further, continuous power output is required during flight. The required output characteristics are subject to variation due to environmental influences such as wind direction, wind speed, and air pressure, as well as pilot skill and control characteristics such as individual differences in flying object. Therefore, there is a risk that the latent heat storage material will not be able to exert its cooling function when needed. In the above respects and in other respects not mentioned, further improvements are required in the monitoring device, the control device, the operation management system, and the program or the like.

It is an object of the present disclosure to provide a monitoring device, a control device, an operation management system, and a non-transitory computer readable medium storing a computer program product, and a control method, which can effectively improve flight safety.

According to an exemplar of the present disclosure, a monitoring device is for monitoring a state of a battery pack mounted on an electric flying object, and the battery pack includes a battery and a latent heat storage material that is capable of changing a phase state between a solid and a liquid. In this case, the monitoring device includes: an acquisition unit configured to acquire information regarding the battery pack; an estimation unit configured to estimate the phase state of the latent heat storage material based on the acquired information; and an output unit configured to output information regarding the phase state.

According to the disclosed monitoring device, the phase state of the latent heat storage material is estimable based on information of the battery pack. In other words, the performance of the latent heat storage material required for cooling the battery can be obtained. Accordingly, flight safety can be further improved.

According to another aspect, a control device for an electric flying object may include: an acquisition unit configured to acquire information regarding the phase state of the latent heat storage material; and a control unit configured to control an output of the battery based on the phase state.

According to the disclosed control device, it is possible to perform a control appropriately in accordance with the phase state, after grasping the phase state of the latent heat storage material or/and the cooling performance. Accordingly, flight safety can be further improved.

For example, an operation management system may be provided with: a monitoring device configured to acquire information regarding a battery pack that is mounted on an electric flying object and to estimate a phase state of a latent heat storage material that is provided in the battery pack; and a control device configured to control an output of a battery provided in the battery pack, based on the phase state of the latent heat storage material.

According to the disclosed operation management system, it is possible to appropriately perform a control in accordance with the phase state, after grasping the cooling performance of the latent heat storage material by estimating the phase state of the latent heat storage material. Accordingly, flight safety can be further improved.

For example, a non-transitory computer readable medium storing a computer program product includes instructions configured to, when executed by at least one processor, cause the at least one processor to: acquire information regarding a battery pack; and estimate the phase state of the latent heat storage material, based on the acquired information regarding the battery pack.

According to the disclosed medium, the phase state of the latent heat storage material is estimable based on the information of the battery pack. In other words, the performance of the latent heat storage material required for cooling the battery is graspable. Accordingly, flight safety can be further improved.

For example, a non-transitory computer readable medium storing a computer program product includes instructions configured to, when executed by at least one processor, cause the at least one processor to: acquire information regarding a phase state of a latent heat storage material provided in the battery pack; and control an output of a battery in the battery pack based on the phase state. Alternatively, a computer-implemented method may be performed by at least one processor to control an electric flying object that drives a drive target including a rotor by using a battery pack. In this case, the method includes acquiring information regarding a phase state of a latent heat storage material provided in the battery pack; and controlling an output of a battery in the battery pack based on the phase state.

According to the disclosed control method, the battery control is performed based on the phase state of the latent heat storage material. That is, by grasping the phase state of the latent heat storage material, that is, the cooling performance, it is possible to perform a control suitable for the phase state. Accordingly, flight safety can be further improved.

The above aspects and exemplars in the specification adopt different technical solutions from each other in order to achieve their respective objects. The objects, features, and advantageous effects disclosed in the specification will become more apparent with reference to the following detailed description and accompanying drawings.

Hereinafter, multiple embodiments will be described with reference to the drawings. The same reference numerals are assigned to the corresponding elements in each embodiment, and thus, duplicate descriptions may be omitted. When only a part of a configuration is described in each embodiment, a configuration of another embodiment described earlier can be applied to the other part of the configuration. Further, not only the combinations of the configurations explicitly shown in the description of the respective embodiments, but also the configurations of the multiple embodiments can be partially combined even if they are not explicitly shown when there is no problem in the combinations in particular.

A monitoring device, a control device, a control method, an operation management system, and a non-transitory computer readable medium storing a computer program product described below may be applied to an electric flying object, as an example.

### First Embodiment

An electric flying object includes a motor (rotating electric machine) as a drive source for movement. The electric flying object may be sometimes referred to as electric airplanes, electric aircraft, or the like. The electric flying object is capable of moving both vertically and horizontally. The electric flying object is capable of moving in a direction having a vertical component and a horizontal component, that is, in a diagonal direction. Examples of the electric flying object include an electric vertical takeoff and landing aircraft (eVTOL), an electric short distance takeoff and landing aircraft (eSTOL), a drone and the like. The eVTOL is an abbreviation of an electric vertical takeoff and landing aircraft. The eSTOL is an abbreviation of an electric short distance takeoff and landing aircraft.

The electric moving object may be any of a manned aircraft and an unmanned aircraft. In a case of the manned aircraft, the electric moving object is operated by a pilot as an operator. In a case of the unmanned aircraft, the electric moving object may be remotely operated by an operator or may be automatically and remotely operated by a control system. As an example, the electric flying object in the present embodiment is an eVTOL.

### <Power Profile>

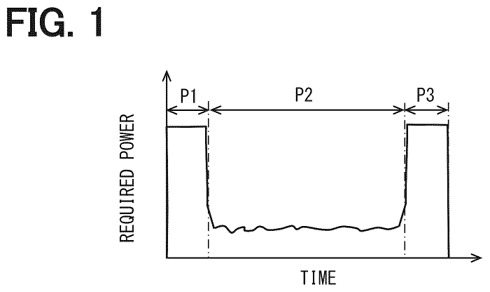

FIG. 1 shows an electrical power profile from takeoff to landing of the eVTOL. It should be noted that the power profile of electric flying objects other than eVTOL is similar to that of eVTOL. A period P1 is referred to as a takeoff period, a takeoff time, a departure period, a departure time, or the like. A period P2 is referred to as a cruise period, a cruise time, or the like. A period P3 is referred to as a landing period, a landing time, an arrival period, an arrival time, or the like. For convenience, in FIG. 1, required electric power, that is, an output, is constant in substantially an entire duration of each of the periods P1 and P3.

The eVTOL ascends from a takeoff point to a cruise start point in the period P1. The eVTOL cruises at a predetermined altitude in the period P2. The eVTOL descends from an end point of the period P2 to a landing point in the period P3. A movement of the eVTOL 10 mainly includes a horizontal direction component in the period P2, and mainly includes a vertical direction component in each of the periods P1 and P3. High output is required continuously for a predetermined time to drive a rotor of the eVTOL 10 during the periods P1 and P3 during which the eVTOL 10 moves in the vertical direction. This high output places a large load on the battery and EPU, which are driving devices for driving the rotor. For example, the battery generates heat and its temperature rises temporarily.

In such a situation, it is possible to suppress temperature rise of the battery, that is, to cool the battery, by utilizing a latent heat of the latent heat storage material. The latent heat storage material is lighter in weight than a circulation type cooler that performs cooling by circulating a refrigerant. Therefore, it contributes weight reduction while maintaining cooling performance, particularly in the electric flying object such as the eVTOL 10. In such manner, it is possible to increase a cruise range.

However, the battery is required to provide high output continuously for a certain period of time during both takeoff and landing. Further, continuous power output is required during flight. Further, the required output characteristics are subject to variation due to environmental influences such as wind direction, wind speed, and air pressure, as well as pilot skill and control characteristics such as individual differences in flying object. Thus, there might be a risk that the latent heat storage material cannot perform its cooling function when needed, and that the battery will become abnormally hot

It is extremely important to improve safety by providing redundancy, by assuming a case where an abnormality has occurred in the battery. However, the above-mentioned temperature abnormality may occur simultaneously in multiple batteries. Therefore, there is a risk that battery redundancy cannot be ensured.

<eVTOL>

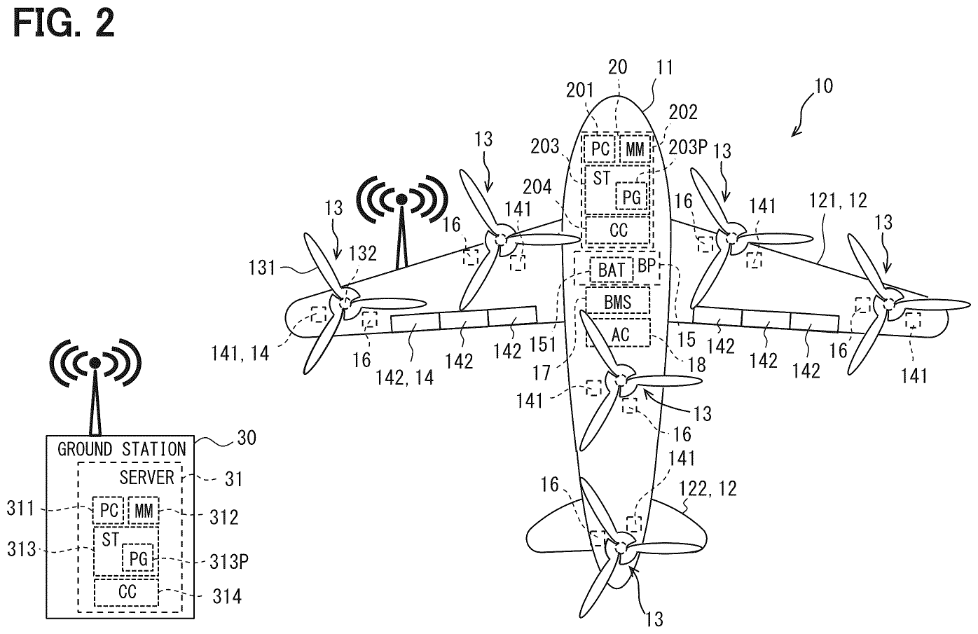

FIG. 2 shows a configuration of the eVTOL and a ground station. As shown in FIG. 2, an eVTOL 10 includes an aircraft body 11, fixed wings 12, rotors 13, a lift adjust mechanism 14, a battery pack 15, an EPU 16, a BMS 17, an air-conditioning device 18, and the like.

The aircraft body 11 is a fuselage of the aircraft. The aircraft body 11 has a shape that extends in a front-rear direction. The aircraft body 11 includes a passenger compartment for passengers and/or a luggage compartment for carrying luggage.

The fixed wings 12 are wings of the aircraft and connected to the aircraft body 11. The fixed wings 12 provide a gliding lift. The gliding lift is a lift generated by the fixed wings 12. As an example, the fixed wings 12 include a main wing 121 and a tailplane 122. The main wing 121 extends to left and right from near a center of the aircraft body 11 in the front-rear direction. The tailplane 122 extends to left and right from a rear part of the aircraft body 11. The shape of the fixed wings 12 is not particularly limited. For example, swept-back wings, delta wings, straight wings may be used.

The multiple rotors 13 are provided on the aircraft. At least one of the rotors 13 may be provided on the fixed wings 12. At least one of the rotors 13 may be provided on the aircraft body 11. The number of the rotors 13 included in the eVTOL 10 is not particularly limited. As an example, the multiple rotors 13 are provided on the aircraft body 11 and the main wings 121, respectively. The eVTOL 10 has six rotors 13.

The rotors 13 each may be referred to as a rotor, a propeller, or a fan. The rotors 13 each have blades 131 and a shaft 132. The blades 131 are attached to the shaft 132. The blades 131 are vanes that rotate together with the shaft 132. The multiple blades 131 extend radially about an axis line of the shaft 132. The shaft 132 is a rotation axis of the rotor 13, and is rotated by a motor of the EPU 16.

The rotor 13 rotates to generate propulsive force. The propulsive force acts on the eVTOL 10 primarily as rotational lift during takeoff and landing of the eVTOL 10. The rotors 13 primarily provide rotational lift during takeoff and landing. The rotational lift is a lift force generated by the rotation of the rotors 13. During takeoff and landing, the rotors 13 may provide only the rotational lift, or may provide both rotational lift and forward thrust. The rotors 13 provide rotational lift when the eVTOL 10 is hovering.

The propulsive force acts on the eVTOL 10 when the eVTOL 10 is cruising. The rotors 13 primarily provide thrust when the eVTL is cruising. During cruising, the rotors 13 may provide thrust only, or may provide both lift and thrust.

The lift adjust mechanism 14 adjusts the gliding lift of the fixed wing 12. The lift adjust mechanism 14 increases or decreases the gliding lift generated by the fixed wing 12. The lift adjust mechanism 14 adjusts the gliding lift by, for example, adjusting at least one of a surface area size, angle of attack (AOA), camber (i.e., curvature of wing), stall AOA, and wing velocity of the fixed wing 12. AOA is an abbreviation of Angle Of Attack. As an example, the lift adjust mechanism 14 includes tilt mechanisms 141 and flaps 142.

The tilt mechanisms 141 are driven to adjust a tilt angle of the rotors 13. The tilt mechanisms 141, together with a motor and an inverter that drive the tilt mechanisms 141, constitute a tilt adjustment device. The tilt adjustment device including the tilt mechanisms 141 may be provided individually for the rotors 13. The tilt mechanisms 141 adjust the tilt angle of the rotors 13 by adjusting a relative inclination of the rotors 13 with respect to the aircraft.

During takeoff and landing, the tilt mechanisms 141 control the tilt angle so that an axis line of each of the rotors 13 approaches a position parallel to the vertical direction. In such manner, the propulsive force generated by the rotation of the rotors 13 acts on the eVTOL 10 primarily as rotational lift. Therefore, the eVTOL 10 is capable of performing short-distance or vertical takeoff and landing.

During cruising, the tilt mechanisms 141 adjust the tilt angle so that the axis line of the rotors 13 approaches a position parallel to the horizontal direction. In such manner, the propulsive force generated by the rotation of the rotors 13 acts on the eVTOL 10 mainly as thrust. Thus, the eVTOL 10 can move forward using forward thrust generated by the rotation of the rotors 13 while using gliding lift from the fixed wing 12. Further, the gliding lift can be adjusted by changing a wing velocity V with thrust.

Although an example in which the tilt mechanisms 141 are provided for each of the rotors 13 has been shown, the present disclosure is not limited to such configuration. For example, the tilt angles of the multiple rotors 13 arranged side by side may be adjusted by a common tilt mechanism. The rotors 13 may be integrated with a part of a wing component, and the part of the wing component and the rotors 13 may be collectively displaced by a tilt mechanism.

The flaps 142 are movable wing pieces, and are provided on the fixed wing 12. The flaps 142, together with motors and inverters that drive the flaps 142, constitute flap adjustment devices. The flaps 142 may sometimes be referred to as high-lift devices. As an example, the multiple flaps 142 are provided on a trailing edge of the main wing 121. Each of the multiple flaps 142 is provided with a motor and an inverter. The flaps 142 may be provided on the tailplane 122 further to the main wing 121. The flaps 142 may be provided on a leading edge of the fixed wing 12.

The flaps 142 adjust the surface area size and camber of the fixed wing 12. For example, the gliding lift acting on the main wing 121 increases by adjusting the flaps 142 provided on the main wing 121 to a lower position. Additionally, the gliding lift can be further increased by moving the flaps 142 in a direction extending beyond the main wing 121.

The lift adjust mechanism 14 is not limited to the tilt mechanisms 141 and the flaps 142 described above. The lift adjust mechanism 14 may include a tilt mechanism that adjusts the relative inclination of the fixed wing 12 with respect to the aircraft body 11. In such case, the angle of attack of the fixed wing 12 can be adjusted. The lift adjust mechanism 14 may include a rotor for thrust provided separately from the rotor 13. In such case, the wing velocity can be adjusted. Further, by providing a rotor for thrust, the rotor 13 may exclusively be used for lift (i.e., rotational lift).

The lift adjust mechanism 14 may include a variable wing. The variable wing can adjust lift by changing the surface area size, camber, and mounting angle of the fixed wing 12. The lift adjust mechanism 14 may include a high-lift device other than the flaps 142, such as slats. The slats are provided on the leading edge of the main wing 121. By moving the slats forward relative to the main wing 121, a gap is defined between the slats and the main wings 121, thereby delaying separation. Thus, lift can be increased up to a greater angle of attack without stalling. That is, the stall AOA can be delayed.

The battery pack (BP) 15 includes a battery (BAT) 151 which is a device for driving the rotor 13 to rotate. The battery 151 supplies electric power to the EPU 16. The battery 151 also supplies electric power to auxiliary devices such as the tilt adjustment device, the flap adjust device, and the air-conditioning device 18, and an ECU 20 described later. Further to the battery 151, the eVTOL 10 may include a fuel cell, a generator, or the like as a power source for supplying electric power to the device. For example, an electric power distributor may be provided.

The number and arrangement of the battery 107B are not particularly limited. As an example, the eVTOL 10 of the present embodiment includes a plurality of battery packs 15 (batteries 151). The multiple batteries 15 may be connected to each other in series and/or in parallel, or may be arranged independently without being connected to each other. The battery 151 is provided redundantly for the EPU 16. In other words, a single EPU 16 can receive electric power from a plurality of batteries 151. The battery pack 15 will be described in detail later.

The EPU includes a motor and an inverter, and rotationally drives the rotor 13 which applies propulsive force to the eVTOL 10. The EPU 16 is a device for driving the rotor 13 to rotate. As an example, the number of the EPUs 16 is the same as the number of the rotors 13. In other words, the eVTOL 10 has six EPUs 16. The EPUs 16 and the rotors 13 are connected in a one-to-one relationship. Alternatively, two or more rotors 13 may be connected to a single EPU 16 via a gear box.

The BMS 17 monitors a state of the batteries 151. The BMS is an abbreviation of a battery management system. The BMS 17 can monitor a voltage, electric current, temperature, internal resistance, SOC, SOH, and other safety-related conditions of the battery 151, such as internal pressure and gas leakage. The SOH is an abbreviation of a state of health. For example, one BMS 17 is provided for one battery 151. The BMS 17 monitors the status of each of the multiple batteries 151.

The air-conditioning device 18 air-conditions the interior of the aircraft by supplying conditioned air to the interior the aircraft. The air-conditioning device 18 is capable of cooling and heating the interior. The air-conditioning device 18 takes in indoor air, for example, and generates conditioned air by adjusting the temperature of the indoor air. The indoor air is an air inside the aircraft. The air-conditioning device 18 is driven by electric power supplied from the battery pack 15 (battery 151). The air- conditioning device 18 includes a compression cycle device (not shown).

The eVTOL 10 further includes the ECU 20 and the like. The ECU is an abbreviation of Electric Control Unit.

### <Battery Pack>

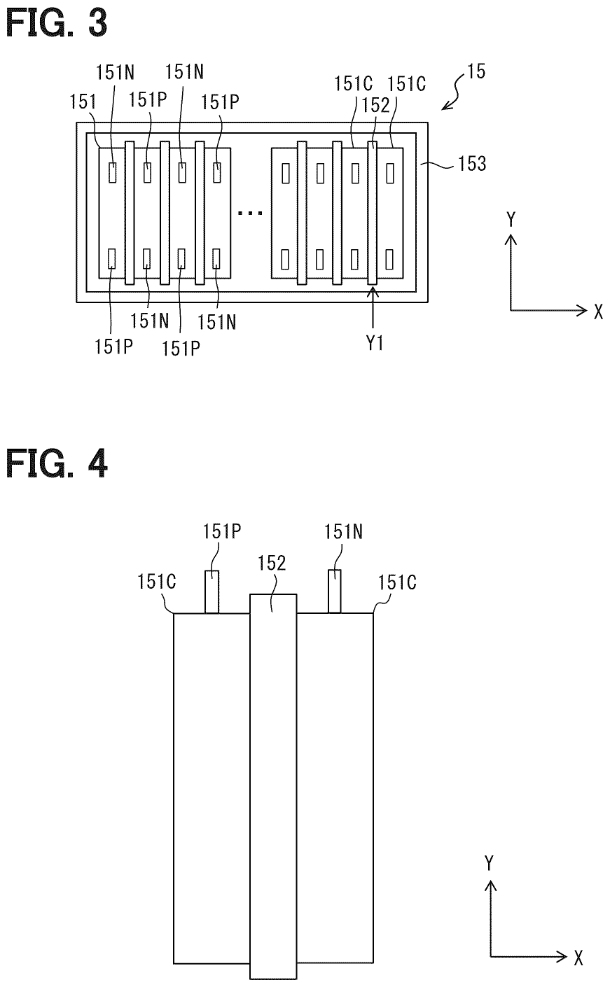

FIG. 3 shows a schematic configuration of a battery pack. FIG. 3 is a top plan view. In FIG. 3, a part of a housing is omitted in order to show battery cells housed in the housing. In FIG. 3, a part of the battery cells and the latent heat storage material is omitted for the sake of convenience. FIG. 4 is a side view of FIG. 3 as viewed from a Y1 direction. In FIG. 4, an extracted stacked structure of two battery cells and one latent heat storage material is shown.

As shown in FIGS. 3 and 4, the battery pack 15 includes a latent heat storage material 152 and a housing 153 in addition to the battery 151 described above. The battery pack 15 also includes bus bars, connectors, fixing members and the like (not shown).

The battery 151 includes a plurality of battery cells 151C. Each of the battery cells 151C is a secondary battery that generates an electromotive voltage by a chemical reaction. The battery cell 151C may be a lithium ion secondary battery, a nickel-hydrogen secondary battery, an organic radical battery or the like. The battery cell 151C may be a secondary battery in which the electrolyte is liquid, or a so-called all-solid-state battery in which the electrolyte is solid.

The battery cells 151C each have a common structure. The number and arrangement of the battery cells 151C are not particularly limited. The multiple battery cells 151C may be connected in series, or in combination of series connection and parallel connection. As an example, the battery cells 151C in the present embodiment are connected in series. The multiple battery cells 151C are arranged side by side in the X direction. The multiple battery cells 151C are stacked in the X direction with the latent heat storage material 152 interposed therebetween. The battery pack 15 may include multiple stacks of the battery cells 151C. An electrically-connected structure of the multiple battery cells 151C is sometimes called as a battery module. The multiple battery cells 151C included in a single battery pack 15, that is, a battery module, corresponds to one of the batteries 15 described above.

Each battery cell 151C includes a power generating element and a battery case that houses the power generating element. The battery case is an outer casing for the battery cell 151C. The battery case may be formed of metal. The shape of the battery cell 151C, i.e., the battery case, is not particularly limited. The battery case may have a cylindrical shape, a rectangular shape or the like. As an example, the battery cell 151C of the present embodiment has a rectangular shape, specifically, a thin and flat shape in a stacking direction.

Each battery cell 151C has electrode terminals 151P, 151N protruding from a top surface. The electrode terminal 151P is electrically connected to a positive electrode of the battery cell 151C. The electrode terminal 151P may be referred to as a positive electrode terminal, a P terminal or the like. The electrode terminal 151N is electrically connected to a negative electrode of the battery cell 151C. The N terminal may be referred to as a negative electrode terminal, a N terminal or the like. The electrode terminals may be referred to as current collecting tabs.

The multiple battery cells 151C are arranged such that the electrode terminals 151P and the electrode terminals 151N are positioned alternately in the X direction. Further, the battery cells 151C are arranged such that the positions of the top surfaces in the Z-direction are substantially equal to each other. In such arrangement, the electrode terminals 151P, 151N of adjacent battery cells 151C are electrically connected by the bus bar (not shown). In other words, the multiple battery cells 151C are connected in series by the bus bars.

The battery 151 of the eVTOL 10 is required to have high capacity as well as high output performance, as will be described later. Therefore, the battery cell 151C that can provide a high capacity and a high output is preferable. From the viewpoint of output, the battery cell 151C having low resistance over a wide SOC range is preferable. In particular, the battery cell 151C having low resistance even in a low SOC region and capable of providing high output is preferable.

The material of the positive electrode of the battery cell 151C may be, for example, LCO, NMC, NCA, LFP, or LMFP. LCO is lithium cobalt oxide (LiCoO2). NMC is lithium nickel cobalt manganese oxide (Li(NiMnCo)O2). NCA is lithium nickel cobalt aluminate (Li(NiCoAl)O2). LFP is lithium iron phosphate (LiFePO4). LMFP is lithium manganese iron phosphate (LiFexMnyPO4). In particular, a positive electrode made of LMFP or a positive electrode made of a blend of LMFP and NMC, which has low resistance in a low SOC region, is preferable.

The material of the negative electrode the battery cell 151C may be, for example, a carbon-based material such as hard carbon or soft carbon, a silicon-based material, a lithium-based material, or a titanium-based material such as LTO or NTO. LTO is lithium titanate (Li4Ti5O12). NTO is niobium titanium oxide (TiNb2O7). In particular, carbon-based and titanium-based negative electrodes, which have low resistance in the low SOC region, are preferred.

The latent heat storage material changes phase between solid and liquid. The latent heat storage material is sometimes called PCM. PCM is an abbreviation of Phase Change Material. The latent heat storage material uses the latent heat of a substance. The latent heat storage material maintains the temperature of the battery cell 151C at a predetermined temperature or within a predetermined temperature range. The latent heat storage material may be a non-hydrate carbon compound, specifically a paraffin compound. Alternatively, the latent heat storage material may be hydrates. Hydrates may be hydrates of sodium acetate, sodium sulfate, sodium nitrate. As an example, the latent heat storage material of the present embodiment is a non-hydrated carbon compound, specifically, a paraffin compound. The phase transition temperature between the solid phase and the liquid phase is set within the range of 30 degree Celsius to 60 degree Celsius.

As an example, in the present embodiment, the latent heat storage materials 152 are arranged alternately with the battery cells 151C in the X direction, which is the stacking direction. The latent heat storage material 152 is in direct contact with the side surface of the battery cell 151C. The latent heat storage material 152 is sandwiched between the battery cells 151C in the X direction.

The arrangement of the latent heat storage material 152 is not limited to the above example. For example, it may come into contact with the bottom surface of the battery cell 151C. The latent heat storage material 152 may be supported by a support member having good thermal conductivity, such as a metal. The latent heat storage material 152 may be indirectly in contact with the battery cell 151C via a thermally conductive member. FIG. 3 shows an example in which the battery cells 151C positioned at both ends in the stacking direction is in contact with the latent heat storage material 152 only on one side surface, specifically only on an inner side surface in the stacking direction. Instead of such structure, the latent heat storage material 152 may be also disposed on an outer side surface of the battery cells 151C positioned at both ends in the stacking direction.

The housing 153 houses the battery cells 151C. The housing 153 may be formed of a metal such as aluminum, or may be formed of a resin material. The latent heat storage material 152 may be housed in the housing 153, or at least a portion of the latent heat storage material 152 may be disposed outside the housing 153. The housing 153 may have a function of transferring heat generated by the battery cells 151C to the latent heat storage material 152. As an example, the housing 153 of the present embodiment is formed (e.g., die-cast formed) using an aluminum-based material. The housing 153 houses the battery cell 151C and the latent heat storage material 152. The heat generated by the battery cell 151C is dissipated to the housing 153 through the latent heat storage material 152.

### <Operation Management System>

The operation management system is a system for planning an operation plan, monitoring an operation status, collecting and managing information related to operation, supporting the operation, and the like. At least a part of functions of the operation management system may be arranged in an internal computer of an eVTOL 10. At least a part of the functions of the operation management system may be arranged in an external computer that can wirelessly communicate with the eVTOL 10. An example of an external computer is a server 31 of a ground station 30 shown in FIG. 2. The ground station 30 can wirelessly communicate with the eVTOL 10. The ground station 30 can wirelessly communicate with other ground stations.

As an example, in the present embodiment, a part of the functions of the operation management system is arranged in an ECU 20 of the eVTOL 10, and a part of the functions of the operation management system is arranged in the server 31 of the ground station 30. The functions of the operation management system are shared between the ECU 20 and the server 31.

As shown in FIG. 2, the ECU 20 includes a processor (PC) 201, a memory (MM) 202, a storage (ST) 203, and a communication circuit (CC) 204 for wireless communication. The processor 201 accesses the memory 202 to execute various processes. The memory 202 is a rewritable volatile storage medium. The memory 202 is, for example, a RAM. The RAM is an abbreviation of Random Access Memory. The storage 203 is a rewritable nonvolatile storage medium. The storage 203 stores a program (PG) 203P to be executed by the processor 201. The program 203P constructs multiple functional units by causing the processor 201 to execute multiple instructions. The ECU 20 may include multiple processors 201.

Similar to the ECU 20, the server 31 includes a processor (PC) 311, a memory (MM) 312, a storage (ST) 313, a communication circuit (CC) 314, and the like. The processor 311 accesses the memory 312 to execute various processes. The memory 312 is a rewritable volatile storage medium, for example, a RAM. The storage 313 is a rewritable nonvolatile storage medium. The storage 313 stores a program (PG) 313P to be executed by the processor 311. The program 313P constructs multiple functional units by causing the processor 311 to execute multiple instructions. The server 31 may include multiple processors 311.

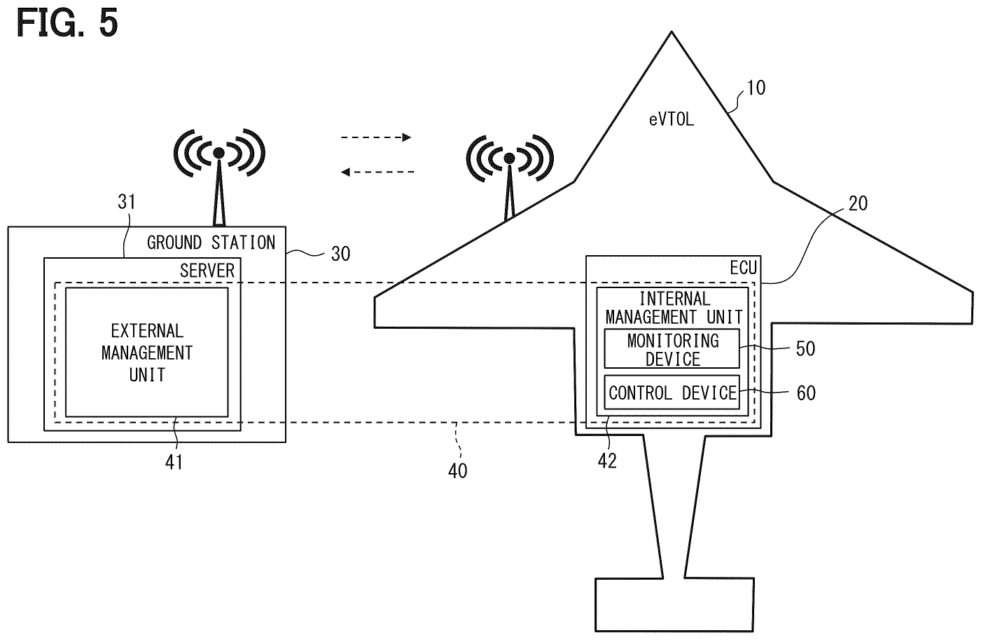

FIG. 5 shows an example of a functional arrangement of an operation management system 40. As shown in FIG. 5, as an example, the operation management system 40 of the present embodiment includes an external management unit 41 and an internal management unit 42. The external management unit 41 is functionally arranged in the server 31 of the ground station 30. The internal management unit 42 is functionally arranged in the ECU 20 of the eVTOL 10. In such manner, a part of the functions of the operation management system 40 is arranged in the server 31, and the other part of the functions is arranged in the ECU 20. The external management unit 41 and the internal management unit 42 can wirelessly communicate with each other. The internal management unit 42 can communicate with various devices arranged in the eVTOL 10 in a wired or wireless manner.

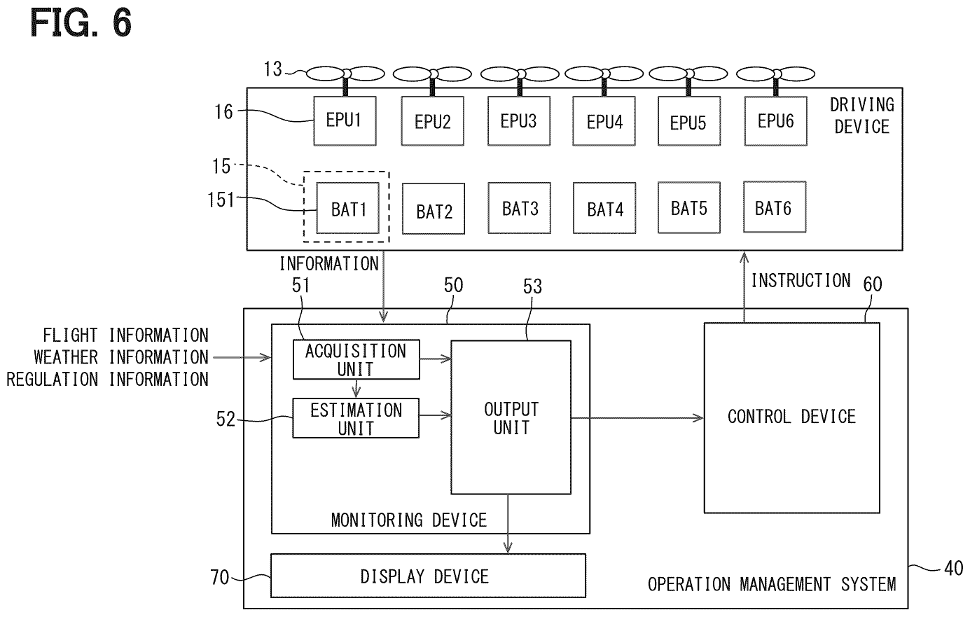

FIG. 6 shows a schematic configuration of the operation management system 40. As described above, the operation management system 40 plans an operation plan, monitors an operation status, collects and manages information related to the operation, supports the operation, and the like. The operation management system 40 includes, as functional units, a monitoring device 50 and a control device 60.

The monitoring device 50 acquires information about the battery pack 15, and monitors a state of the battery pack 15. The monitoring device 50 estimates a phase state of the latent heat storage material 152 based on the acquired information. The monitoring device 50 may determine whether a predetermined condition is satisfied based on a degree of temporary deterioration. Details of the monitoring device 50 will be described later.

The monitoring device 50 may be functionally arranged in the ECU 20 of the eVTOL 10 or in the server 31 of the ground station 30. The monitoring device 50 may be arranged as part of the external management unit 41 or as part of the internal management unit 42. The monitoring device 50 may be positioned separately from the BMS 17, or at least a part of the monitoring device 50 may be positioned within the BMS 17. As an example, the monitoring device 50 of the present embodiment is functionally arranged in the ECU 20 of the eVTOL 10. The monitoring device 50 is arranged as a part of the internal management unit 42.

The control device 60 controls an output of the battery 151 based on a phase state of the latent heat storage material 152. As an example, the control device 60 of the present embodiment acquires the phase state from the monitoring device 50, and controls the output of the battery 151 based on the phase state. The details of the control device 60 will be described in other embodiments.

The control device 60 may be functionally arranged in the ECU 20 of the eVTOL 10 or in the server 31 of the ground station 30. The control device 60 may be arranged as part of the external management unit 41 or as part of the internal management unit 42. As an example, the control device 60 of the present embodiment is functionally arranged in the ECU 20 of the eVTOL 10. The control device 60 is arranged as part of the internal management unit 42. The control device 60 is configured by the common arithmetic processing device as the monitoring device 50.

The operation management system 40 may further include a display device 70. The display device 70 may be arranged in the eVTOL 10 and/or in the ground station 30. The display device 70 displays, for example, monitoring results and determination results acquired by the monitoring device 50. In such manner, relevant persons on board the aircraft or at the ground station 30 are notified of monitoring results, and the like. The display device 70 may display the results of calculations performed by the control device 60 and other functional units.

The operation management system 40 also includes an operation planning device (not shown). The operation planning device plans an operation plan of the eVTOL 10 based on, for example, information received from a terminal which is not shown. The input information includes, for example, information regarding a departure point and an arrival point. The operation planning device may create an operation plan taking into account battery information and weather information.

### <Monitoring Device>

As described above, the program 203P causes the processor 201 to execute a plurality of instructions, thereby constructing the monitoring device 50, which is a functional unit.

The monitoring device 50 monitors the state of the battery pack 15. The monitoring device 50 may monitor the state of the battery pack 15 by monitoring a predetermined parameter on a battery cell basis. The unit of monitoring may be a battery stack or a battery pack. The monitoring device 50 monitors the state of the latent heat storage material 152 as a state of the battery pack 15. As shown in FIG. 6, the monitoring device 50 includes an acquisition unit 51, an estimation unit 52, and an output unit 53.

The acquisition unit 51 acquires information about the battery pack 15. The acquisition unit 51 acquires information about the battery 151 and/or information about the latent heat storage material 152. As an example, the acquisition unit 51 in the present embodiment acquires information about the battery pack 15 from the BMS 17. The acquisition unit 51 may acquire the battery pack information from, for example, a sensor (not shown).

The acquisition unit 51 may acquire at least one of flight information, weather information, and regulation information further to the battery pack information. The flight information may include, for example, flight altitude, flight speed, attitude (angle), flight position, etc. of the current flight. Further to information on the current flight, flight information may include information such as flight altitude and flight speed based on the operation plan. The weather information may include, for example, a wind direction, a wind speed, an atmospheric pressure and the like. Information on regulations and rules may include, for example, whether or not there are noise regulations, rules regarding flight altitude, and the like. The acquisition unit 51 may acquire history information of past flights.

The estimation unit 52 estimates the phase state of the latent heat storage material 152 based on the acquired battery pack information. The estimation unit 52 may estimate whether the phase is a solid phase or not. In other words, it may be estimated whether the state of the material is in a solid phase or a liquid phase. The estimation unit 52 may estimate the degree of liquefaction as the phase state. The estimation unit 52 may estimate the remaining amount of cooling effect (remaining effect) of the latent heat storage material 152 as the phase state. The estimation unit 52 estimates the phase state by, for example, calculation. The calculation of the phase state may be an actual measurement calculation based on an actual measurement value, or a predictive calculation based on a predicted value. The estimation unit 52 may estimate the phase state based on a map or a predictive model.

The estimation unit 52 may estimate the phase state using raw data of the battery pack 15 acquired from the BMS 17, such as the voltage, current, and temperature of the battery 151. The estimation unit 52 may estimate the phase state using the temperature of the latent heat storage material 152 or the like. The estimation unit 52 may acquire the data calculated by the BMS 17, and may determine the phase state by performing additional calculations. The estimation unit 52 may estimate the phase state before the flight, or may estimate the phase state during the flight. The phase state may be estimated after the flight.

The output unit 53 outputs an estimation result of the estimation unit 52 to the outside of the monitoring device 50. As an example, the output unit 53 in the present embodiment outputs the phase state to the control device 60. The output unit 53 may output the estimation result of the estimation unit 52 to the display device 70. The output unit 53 may output other information, for example, information acquired by the acquisition unit 51, to the control device 60 or the display device 70.

### <Monitoring Method>

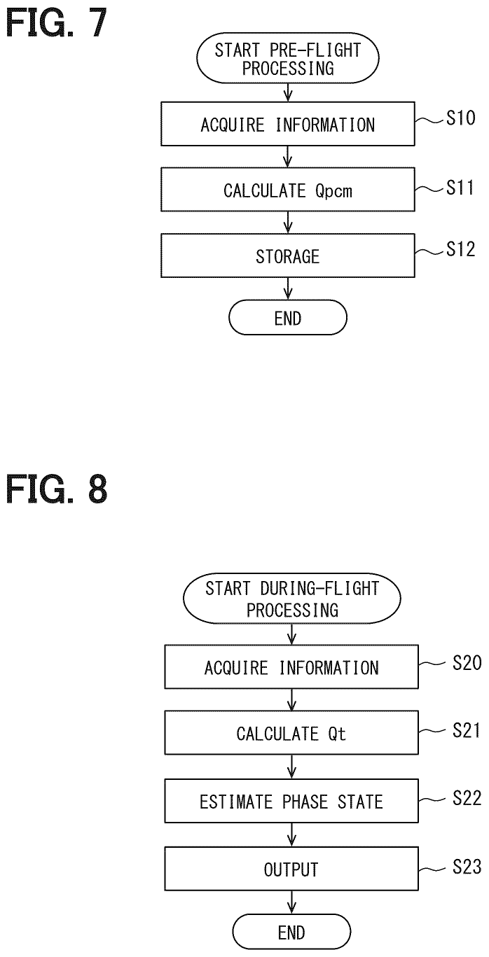

FIGS. 7 and 8 show an example of a monitoring method. The execution of the processing of each functional block of the monitoring device 50 by the processor 201 corresponds to the execution of the monitoring method.

The monitoring device 50 first performs a pre-flight processing shown in FIG. 7. The monitoring device 50 may perform pre-flight processing before consuming electric power of the battery 151. The monitoring device 50 may perform pre-flight processing, for example, before driving the rotor 13 (EPU 16). The monitoring device 50 may perform pre-flight processing, for example, before moving the aircraft on the ground. The monitoring device 50 may perform pre-flight processing, for example, after charging. The monitoring device 50 may perform the process shown in FIG. 7 at least once before a flight.

As shown in FIG. 7, first, the monitoring device 50 acquires information about the battery pack 15 (step S10). The acquisition unit 51 of the monitoring device 50 acquires an initial temperature Tini and SOC of the battery 151. As an example, in the present embodiment, the acquisition unit 51 acquires a voltage Vocv of the battery 151 from the BMS 17, and acquires the SOC from an SOC-OCV curve. The OCV is an abbreviation of an open circuit voltage. The voltage Vocv is an open circuit voltage of the battery 151. The acquisition unit 51 may acquire the SOC from the BMS 17.

Next, the monitoring device 50 calculates an stored heat amount Qpcm of the latent heat storage material 152 based on the acquired information (step S11). The stored heat amount Qpcm indicates the cooling effect that the latent heat storage material 152 has before the flight. The stored heat amount Qpcm indicates a phase state before the flight. The estimation unit 52 of the monitoring device 50 calculates the stored heat amount Qpcm based on Equation 1.

Qpcm=m·{c (Tmp−Tini)+L+c (Tlim−Tmp)} (Equation 1)

Among the parameters related to the latent heat storage material 152, m is a payload weight [kg], c is a specific heat [J/(kg·K)], Tmp is a melting point [K], and L is a latent heat [J/kg]. Tlim is a limit temperature [K] of the battery 151. The limit temperature Tlim is a temperature acquired by subtracting a margin from an upper limit temperature of the battery 151. The estimation unit 52 calculates the stored heat amount Qpcm based on the temperature Tini. The other parameters are stored in advance in a storage medium.

Next, the monitoring device 50 stores the stored heat amount Qpcm in a storage medium (step S12), and ends the series of processes.

The monitoring device 50 performs a during-flight processing shown in FIG. 8 at a predetermined timing during the flight. The monitoring device 50 repeatedly performs the process shown in FIG. 8 during the flight. The monitoring device 50 may repeatedly perform the during-flight processing from takeoff to landing. The monitoring device 50 may repeatedly perform the during-flight processing during the cruise time P2

As shown in FIG. 8, first, the monitoring device 50 acquires information about the battery pack 15 (step S20). The acquisition unit 51 of the monitoring device 50 acquires a voltage Vccv and an electric current I of the battery 151 during flight, i.e., during discharging. The voltage Vccv is a closed circuit voltage. CCV is an abbreviation of Closed Circuit Voltage. The acquisition unit 51 calculates a current SOC(t) from the discharge amount (∫ldt), which is an integrated value of the current I since the start of the flight. Then, the acquisition unit 51 estimates the voltage Vocv from the SOC(t) and the SOC-OCV curve.

Next, the monitoring device 50 calculates a total heat generation amount Qt (step S21). The estimation unit 52 of the monitoring device 50 first calculates the current heat generation amount q(t) based on Equation 2. x is a correction coefficient, which is determined in advance based on the rate characteristics of the battery during prototyping, etc.

q(t)=x·(Vccv−Vocv)·I (Equation 2)

The estimation unit 52 calculates a total heat generation amount Qt (∫q(t)dt), which is an integrated value of the heat generation amount q(t) since the start of the flight.

Next, the monitoring device 50 estimates a phase state of the latent heat storage material 152 (step S22). The estimation unit 52 of the monitoring device 50 estimates the phase state during the flight using the pre-flight stored heat amount Qpcm stored in the storage medium and the integrated value Qt of the amount of heat generated during the flight (total amount of heat generated during the flight). As an example, the estimation unit 52 of the present embodiment calculates a remaining effect W of the cooling performance of the latent heat storage material 152 as the phase state. The remaining effect W is obtainable by subtracting a total heat generation amount Qt from a stored heat amount Qpcm.

Further, a heat dissipation amount Qw in the air may be used to calculate the remaining effect W. The heat dissipation amount Qw is stored in advance in a storage medium. By subtracting the total heat generation amount Qt and the heat dissipation amount Qw from the stored heat amount Qpcm, the current stored heat amount, that is, the remaining effect W, can be estimated with high accuracy. Instead of the remaining effect W, the degree of liquefaction may be calculated. When it is completely in a solid phase, the degree of liquefaction is 0%, and when it is completely in a liquid phase, the degree of liquefaction is 100%. The degree of liquefaction before flight is essentially (ideally) 0%. Therefore, the degree of liquefaction is estimable from the stored heat amount Qpcm before the flight and the stored heat amount at the current time (i.e., the remaining effect W).

The monitoring device 50 estimates the phase state of the latent heat storage material 152 for a unit of battery pack, that is, for each battery. In a configuration including multiple battery packs 15, the monitoring device 50 estimates the phase state of the latent heat storage material 152 of all battery packs 15. The monitoring device 50 may estimate a total phase state of the latent heat storage material included in the eVTOL 10.

Next, the monitoring device 50 outputs information including the estimation result of the phase state to the outside of the monitoring device 50 (step S23), and ends the series of processes. As an example, the output unit 53 of the monitoring device 50 in the present embodiment outputs information including the phase state to the control device 60. Further to the phase state, the monitoring device 50 may output at least one of the flight information, the weather information, and the regulation information to the control device 60. In such case, the acquisition unit 51 acquires at least one of the flight information, the weather information, and the regulation information in the processing of step S10 and/or step S20. The monitoring device 50 may output at least a portion of the information to the display device 70.

### <Summary of First Embodiment>

As described above, the monitoring device 50 of the present embodiment acquires information about the battery pack 15, and estimates the phase state of the latent heat storage material 152 based on such information. The monitoring device 50 outputs information regarding the phase state. Since the performance of the latent heat storage material 152 required for cooling the battery 151 is graspable in such manner, appropriate processing that leads to flight safety, such as flight control, becomes possible. Accordingly, flight safety is improvable.

As an example, the monitoring device 50 of the present embodiment calculates the stored heat amount Qpcm in the latent heat storage material 152 before the flight and the integrated value Qt of the amount of heat generated by the battery 151 during the flight based on the acquired information. Then, the monitoring device 50 estimates the phase state during the flight using the stored heat amount Qpcm and the integrated value Qt of the amount of generated heat. In such manner, the phase state during the flight is estimable with high accuracy. In such manner, it is possible to perform flight control according to the phase state, for example, thereby improving flight safety.

The operation management system 40 of the present embodiment includes the monitoring device 50 and the control device 60. The monitoring device 50 acquires information about the battery pack 15, and estimates the phase state of the latent heat storage material 152 based on such information. The control device 60 controls the output of the battery 151 based on the phase state. In such manner, by understanding the phase state of the latent heat storage material 152, i.e., the cooling performance of the latent heat storage material 152, appropriate control that leads to flight safety is performable. Accordingly, flight safety is improvable.

The program (program 203P) of the present embodiment includes (a) causing at least one processor 201 (processing unit) to acquire information of the battery pack 15 and (b) estimating the phase state of the latent heat storage material 152 based on the acquired information. According to such program, the phase state of the latent heat storage material 152, that is, the performance required for cooling the battery 151, is graspable. Accordingly, flight safety is improvable.

### <Modification>

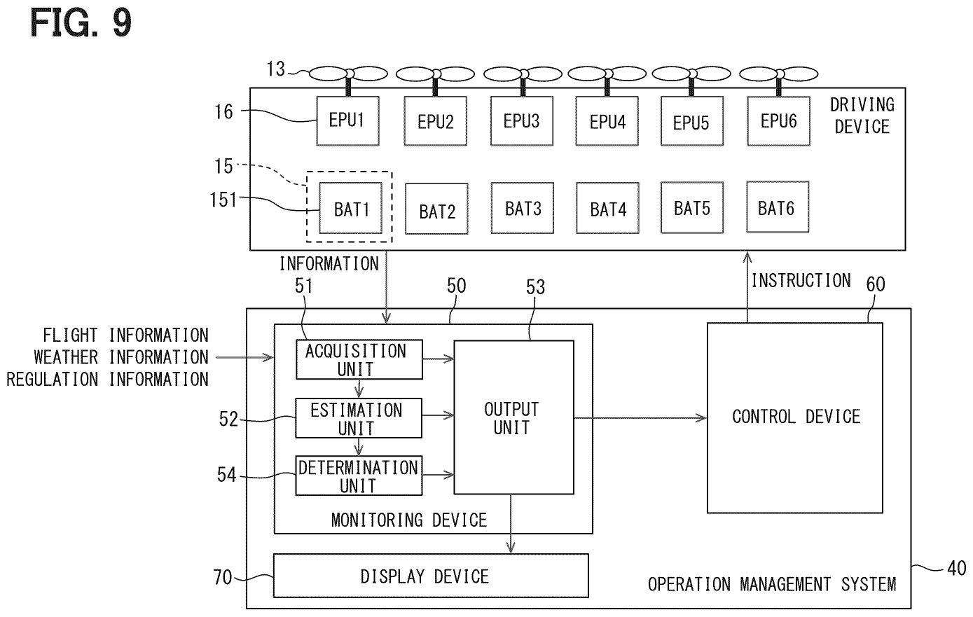

The timing of estimating the phase state is not limited to during flight. For example, phase states may be estimated before the flight. Further, a need for takeoff restriction may be determined based on the phase state estimated before the flight. In such case, as shown in FIG. 9, the monitoring device 50 includes a determination unit 54.

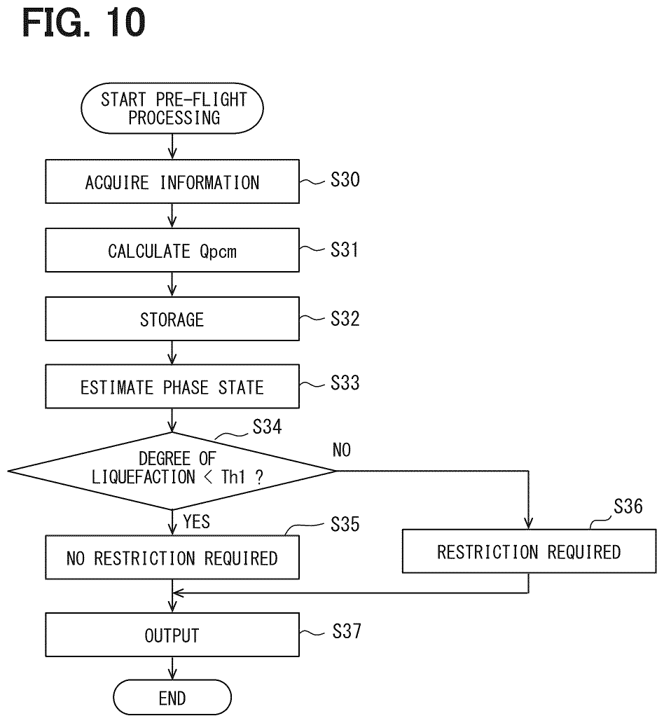

FIG. 10 illustrates an example of a pre-flight monitoring method. The processes in steps S30, S31, and S32 are common (identical) to the processes in steps S10, S11, and S12 shown in FIG. 7. The estimation unit 52 of the monitoring device 50 estimates the phase state based on the stored heat amount Qpcm (step S33). The ideal amount of stored heat in a completely solid-phase state, that is, with a liquefaction degree of 0%, is stored in advance in the storage medium. The estimation unit 52 of the monitoring device 50 estimates the phase state based on such ideal amount of stored heat and the stored heat amount Qpcm. The estimation unit 52 estimates the degree of liquefaction, for example, as the phase state. Alternatively, the remaining effect may be estimated.

After estimating the phase state, the determination unit 54 of the monitoring device 50 determines, for example, whether or not the degree of liquefaction is less than a predetermined threshold value Th1 (step S34). When the degree of liquefaction is less than the threshold value Th1, the monitoring device 50 determines that there is a sufficient cooling effect to absorb the heat generated by the battery 151 during takeoff, and therefore determines that takeoff restriction is not required (step S35). When the degree of liquefaction is equal to or greater than the threshold value Th1, the monitoring device 50 determines that the cooling effect is insufficient to absorb the heat generated by the battery 151 during takeoff, and therefore determines that takeoff restriction is required (step S36). Then, the monitoring device 50 outputs the result of the determination as to whether or not the restriction is required to the outside of the monitoring device 50 (step S37), and ends the series of processes. The monitoring device 50 outputs the result of the determination as to whether or not the restriction is required, for example, to the control device 60 and/or the display device 70.

Note that the threshold value Th1 (determination criterion) used for the requirement determination may be set based on data acquired through experiments or the like. It may also be set based on the history information of past flights. For example, the threshold value Th1 may be set based on the history information of past flights that match the aircraft type and departure and/or arrival points with the target flight. The history information is information regarding phase states, such as degree of liquefaction and takeoff restrictions. Since the operation plan of the eVTOL 10 is finite, and the repetition frequency is high, the history information can be utilized. In particular, since the history information with matching takeoff points and aircraft type, which are prone to errors, is used, appropriate threshold values can be set.

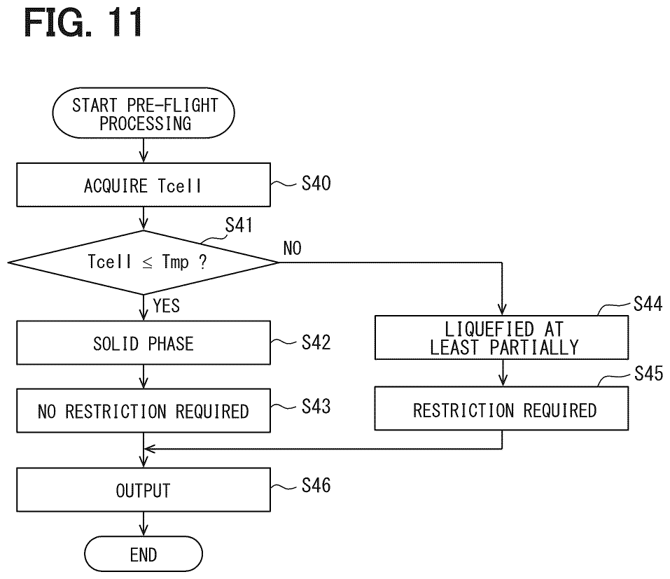

FIG. 11 illustrates an example of a pre-flight monitoring method. First, the monitoring device 50 acquires temperature Tcell of the battery 151 as information about the battery pack 15 (step S40). The temperature Tcell may be an average or maximum temperature of the battery cells. The temperature Tcell may be a predetermined temperature value of the battery 151. Next, the monitoring device 50 determines whether the temperature Tcell is equal to or lower than the melting point Tmp of the latent heat storage material 152 (step S41).

When the temperature Tcell is equal to or lower than the melting point Tmp, it is determined that the latent heat storage material 152 is in a solid phase (step S42), and it is determined that no takeoff restriction is required (step S43). When the temperature Tcell is higher than the melting point Tmp, it is determined that the latent heat storage material 152 is at least partially in a liquid phase, that is, liquefied (step S44), and it is determined that takeoff restriction is required (step S45). Then, the monitoring device 50 outputs the result of the determination as to whether or not the restriction is required to the outside of the monitoring device 50 (step S46), and ends the series of processes. The monitoring device 50 outputs the result of the determination as to whether or not the restriction is required, for example, to the control device 60 and/or the display device 70.

Note that, in the monitoring method shown in FIGS. 10 and 11, an example of determining whether or not takeoff restriction is required is shown, but the present disclosure is not limited to such configuration. An estimated phase state may be acquired without determining whether or not takeoff restriction is required. The result of the determination as to whether or not takeoff restriction is required and the phase state may be output.

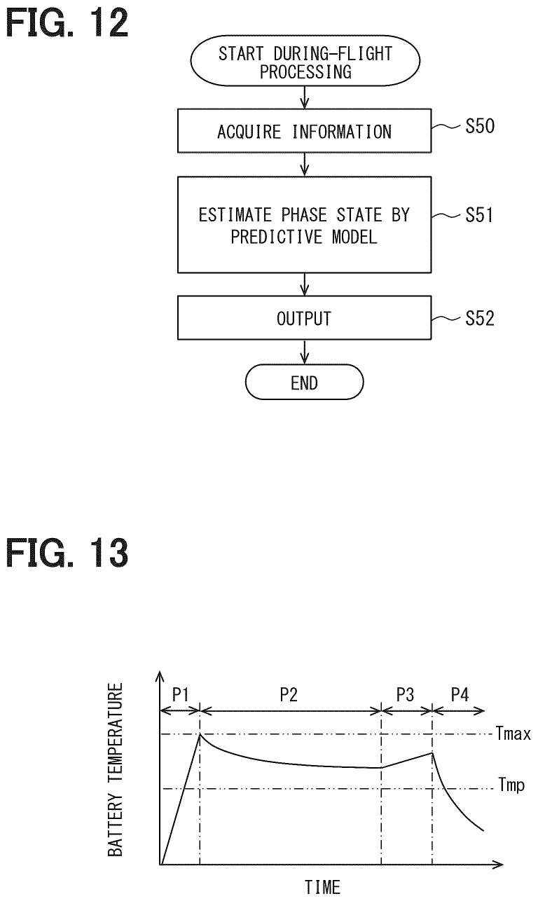

The method of estimating the phase state is not limited to the above example. The phase state may be estimated based on the history information from the past flights. For example, the estimation may be performed using a prediction map. Alternatively, it may be determined using a predictive model such as multiple regression. For example, the phase state may be estimated using a predictive model generated using machine learning. FIG. 12 shows an example of a monitoring method performed during the flight. The monitoring device 50 acquires information about the battery pack 15 (step S50), and then estimates the phase state based on a predictive model generated using machine learning (step S51). Then, the monitoring device 50 outputs the estimated phase state (step S52), and ends the series of processes.

By using a predictive model generated by machine learning, it is possible to improve the accuracy and speed of estimation, even when there are many explanatory variables. Further, construction of the predictive model can be facilitated by generating the predictive model by machine learning. Further, the estimation accuracy is further improvable by increasing the number of explanatory variables. A model generation unit that generates a predictive model through machine learning may be provided in the monitoring device 50 or may be provided outside the monitoring device 50 in the operation management system 40.

Note that the explanatory variables may be referred to as input variables, input items, or the like. The target variable is acquired by inputting the explanatory variables into the predictive model. The phase state of the latent heat storage material 152 is acquired as the target variable. The target variables may be referred to as output variables, output items, or the like. The estimation accuracy of the phase state is improvable by constructing a predictive model or prediction map using important factor parameters as the explanatory variables.

FIG. 13 shows an example of the change in the battery temperature during the flight in a configuration including the latent heat storage material 152. During a takeoff period P1, the battery temperature rises and exceeds the melting point Tmp of the latent heat storage material 152 midway through the takeoff period P1. However, the latent heat of the latent heat storage material 152 suppresses the rise in the battery temperature. After an end of the takeoff period P1, when the aircraft transitions to the cruise period P2, the battery temperature drops to an equilibrium temperature according to the flight conditions. Then, during a landing period P3, the battery temperature rises again, and during a period P4 after landing, it drops to approximately the same temperature as the outside air temperature. The latent heat storage material 152 absorbs heat in the periods P1 and P3, and releases heat in the periods P2 and P4

For example, a maximum temperature Tmax of the battery 151 changes depending on the phase state of the latent heat storage material 152. Further, the time required to reach the maximum temperature Tmax also changes. Further, the time required to reach the equilibrium temperature from the maximum temperature Tmax and the rate of temperature drop also change. In other words, there is a correlation between (a) the temperature rise at takeoff and/or the temperature drop after the start of cruising, and (b) the phase state of the latent heat storage material 152. Therefore, for example, the history information regarding the drop in the battery temperature when transitioning from the takeoff period P1 to the cruise period P2 may be used as teacher data (factor parameters). Further, the history information regarding the rise rate in the battery temperature relative to the integrated value of the amount of heat generated by the battery 151 may be used as teacher data (factor parameters).

As described above, the battery is required to provide high output continuously for a predetermined period of time during both takeoff and landing. Further, continuous power output is required during the flight. Further, the required output characteristics are subject to variation due to environmental influences such as wind direction, wind speed, and air pressure, as well as pilot skill and control characteristics such as individual differences in flying object. Therefore, the history information may be information about past phase states in which the takeoff and/or landing points and aircraft types match those of the target flight. By utilizing the history information from takeoff and landing points, which is prone to prediction errors, the estimation accuracy of the phase state is improvable. Ease of operation, output characteristics, etc. vary depending on the model (type) of the eVTOL 10. In such manner, the estimation accuracy of the phase state is further improvable.

For example, past phase states that match the takeoff and/or landing points and aircraft type of the target flight may be used as estimation of the phase states for the current flight. Further, the phase state may be estimated by a predictive model using the history information of the past flights whose takeoff and/or landing points and aircraft types match those of the target flight as one of the above-mentioned factor parameters. As an example, the above-mentioned information on the drop in the battery temperature and the information on the rise rate in the battery temperature may be combined.

As the factor parameters, history information on the flight altitude, history information on flight route, history information on time range of takeoff and landing, etc. may be added. The flight altitude affects, for example, an air density, the atmospheric pressure, the outside air temperature, and an output required for an altitude. The flight route affects, for example, a flight distance and the outside air temperature. The time range affects, for example, the outside air temperature and a waiting time. By adding the other factor parameters that are prone to error, the estimation accuracy is further improvable.

Further, the factor parameters may include the weather information for the takeoff and/or landing points of the target flight, control characteristics information, payload weight, and the like for the target flight. Weather conditions at the takeoff and landing points, such as wind direction, wind speed, air pressure, etc., affect the operation of the eVTOL 10 during takeoff and landing. The estimation accuracy is further improvable by adding the weather information about the takeoff and landing points to the factor parameters. A variation in aircraft factors and a variation in pilot factors appear in (i) the moving speeds in the vertical direction, the horizontal direction, and the oblique direction, (ii) the adjustment time of the aircraft position with respect to the arrival point, the transition time from the cruise mode to the arrival (landing) mode, and the like. By adding the control characteristics information such as the moving speed, the adjustment time, and the transition time as the control characteristics information to the factor parameters, the estimation accuracy is further improvable. The payload weight is weights of passengers (persons), articles to be carried, or the like. As the payload weight increases, a higher output is required. By adding the payload weight to the factor parameters, the estimation accuracy is further improvable.

It should be noted that the factor parameters that significantly affect the maximum output and the battery temperature during the takeoff and landing are not limited to the above examples. In a case of the predictive model generated by machine learning, when the machine learning progresses together with the accumulation of the history information, a new factor parameter can be extracted as the other information.

Although the combination of the monitoring device 50 and the control device 60 is shown, the present disclosure is not limited to such configuration. The monitoring device 50 may be provided independently. For example, the output destination of the monitoring device 50 is not limited to the control device 60.

### Second Embodiment

The present embodiment is a modification of a preceding embodiment that serves as a basic configuration, and may incorporate description of the preceding embodiments. In the preceding embodiment, a configuration capable of monitoring the phase state has been described in detail. In the present embodiment, a configuration capable of controlling the output of a battery based on the phase state will be described.

### <Control Device>

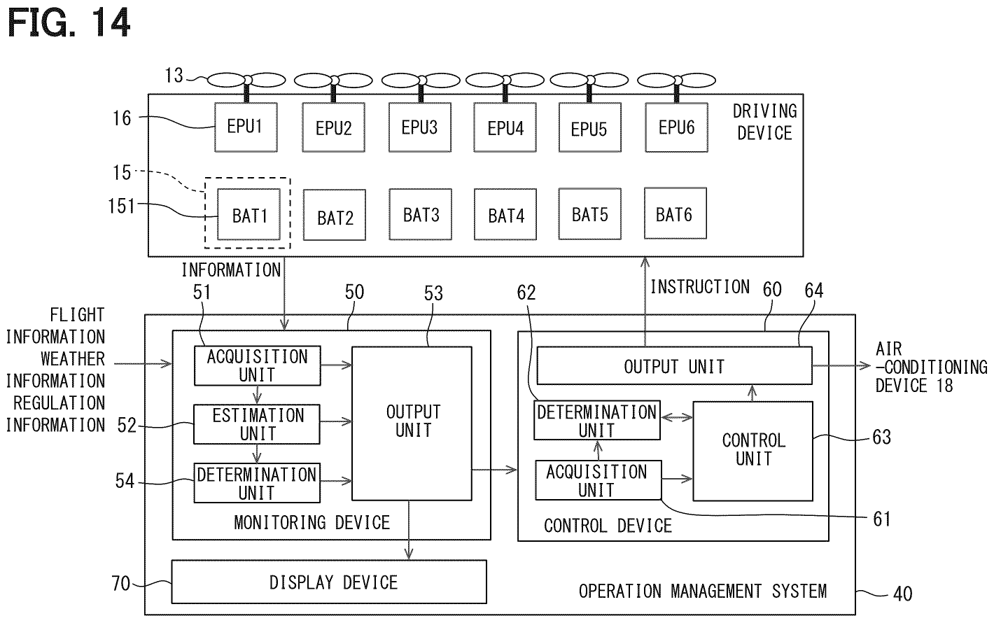

FIG. 14 is a diagram showing a schematic configuration of a control device 60 and an operation management system 40 according to the present embodiment. FIG. 14 corresponds to FIGS. 6 and 9. As shown in FIG. 14, the control device 60 includes an acquisition unit 61, a determination unit 62, a control unit 63, and an output unit 64.

The acquisition unit 61 acquires information regarding the phase state of a latent heat storage material 152. As an example, the acquisition unit 61 in the present embodiment acquires the phase state from a monitoring device 50. However, the phase state is not limited to the one that is acquired by monitoring by the monitoring device 50. The phase state may be estimated based, for example, on operation plan and history information from the past flights. The estimation may be performed by a functional unit (not shown) of the control device 60. In the operation management system 40, a functional unit other than the monitoring device 50 and the control device 60 may perform the estimation.

For example, when it is expected that the degree of liquefaction, which is a phase state, will be greater than a threshold value, which is a predetermined standard, based on history information at a specific time during operation, such a degree of liquefaction may be used as an estimation value of the phase state. The history information is preferably history information of a past flight whose aircraft type and takeoff and/or landing points match those of the current flight.

The acquisition unit 61 may also acquire other information about a battery pack 15, such as the battery temperature. The acquisition unit 61 may acquire information other than information relating to the battery pack 15, e.g., at least one of flight information, weather information, and regulation information. As an example, the acquisition unit 61 in the present embodiment acquires at least one of flight information, weather information, and regulation information from the monitoring device 50. The acquisition unit 61 may acquire the above-mentioned information from other device other than the monitoring device 50.

The determination unit 62 performs a predetermined determination based on the information acquired by the acquisition unit 61. The determination unit 62 compares, for example, the phase state with a threshold value that is a predetermined standard, and outputs a determination result to the control unit 63. The determination unit 62 compares the degree of liquefaction, which is the phase state, with a threshold value, for example, and determines whether to execute a normal mode or a fail-safe mode. A mode determination threshold is a threshold for determining whether or not fail-safe control is required. Such a threshold value is set so as not to cause a shortage of cooling performance required during landing. When the degree of liquefaction exceeds a threshold value, indicating a possibility of shortage, the control unit 63 performs fail-safe control. The threshold value may be set with a predetermined margin taken into account, or may be changed based on the operation plan for the current flight. The determination unit 62 may perform a mode determination based on a remaining effect W instead of the degree of liquefaction.

The determination unit 62 may determine whether or not it is necessary to perform air-conditioning control, for example, when normal control is being performed. The determination unit 62 compares the degree of liquefaction, which is, for example, the phase state, with a threshold value, and determines that air-conditioning control is necessary when the degree of liquefaction is equal to or greater than the threshold value. The threshold value used for the determination may be set, for example, based on data acquired from a previous experiment. The determination unit 62 may perform a mode determination based on a remaining effect W instead of the degree of liquefaction.

The determination unit 62 may compare the battery temperature with a predetermined temperature, for example, when the fail-safe control is being performed. The determination unit 62 determines whether to use a gliding landing or a propellant landing based on the magnitude relationship between the battery temperature and a predetermined temperature.

As described above, the control unit 63 controls the output of a battery 151 based on the phase state. The control unit 63 performs a predetermined control according to the result of the determination by the determination unit 62. The control unit 63 may indirectly control the output of the battery 151 by controlling a drive target that is driven by the electric power of the battery 151. The drive target includes a rotor 13, that is, an EPU 16. The control unit 63 may control the output of the battery 151 by performing flight control including processing for controlling the drive of a rotor 13. Flight control may include processes for adjusting a tilt mechanism 141 and flaps 142. The drive target may include an auxiliary device such as an air-conditioning device 18. The control unit 63 may control the output of the battery 151 by controlling the drive of an auxiliary machinery. Flight control and accessory control may be combined.

As an example, the control unit 63 in the present embodiment controls the output of the battery 151 by controlling the drive target. In other words, the control unit 63 controls the flight of an eVTOL 10. The control unit 63 performs various processes related to flight control of the eVTOL 10 based on information acquired from the monitoring device 50. The control unit 63 performs flight control to fly the eVTOL 10 in a flight state according to an operation by a pilot as an operator, remote operation by an operator, or control by a control system.

Here, a lift L acting on the eVTOL is expressed by Equation 3. A drag D is expressed by Equation 4. In the Equations 3 and 4, p is an air density, V is a wing velocity, and S is a surface area size of the fixed blade. The wing velocity V may be called as an airspeed, flight speed, or the like. CL is a lift coefficient and CD is a drag coefficient.

L=(CL·ρ·V2·S)/2 (Equation 3)

D=(CD·ρ·V2·S)/2 (Equation 4)

The lift L and the drag D increase as the wing velocity V (flight speed) increases, and decrease as the wing speed decreases. The lift L and the drag D decrease as the flight altitude increases because the air density ρ decreases, and increase as the flight altitude decreases because the air density ρ increases. The lift L and the drag D can be varied by a lift coefficient CL and a drag coefficient CD, which are determined by the surface area size and an airfoil shape of the fixed wing.

Therefore, for stable and safe flight, it is preferable to adjust the lift, specifically the rotational lift and gliding lift, so that the flight speed and flight altitude fall within a permissible range based on the rules and regulations in the flight area.

The control unit 63 may reduce the drag D of the aircraft to ensure the required thrust. For example, when the rotor 13 is stored inside the aircraft body or inside a fixed wing 12 when stopped, it is possible to reduce the drag D and the required thrust. When the required thrust can be secured, the control unit 63 may stop the output of at least a portion of the batteries 151. The control unit 63 may ensure the thrust and lift required for flight by driving the rotor 13 using the output of the other batteries 151 excluding the battery 151 whose output has been stopped, and by adjusting the lift using a lift adjust mechanism 14. When the thrust required for flight is zero, i.e., under conditions where so-called glider flight is permitted, the control unit 63 may temporarily stop output from all batteries 151.

The control unit 63 adjusts the rotational lift by controlling the drive of the rotor 13. The control unit 63 generates a control signal indicating a target rotation speed for each rotor 13 to achieve an instructed flight state. The control unit 63 outputs a control signal indicating a target rotation speed to a drive circuit (driver) (not shown) that drives an inverter of the EPU 16. The drive circuit drives a motor of the EPU 16 via the inverter so that the rotation speed of the rotor 13 coincides with a target rotation speed. The control unit 63 reduces the rotation speed of the rotor 13 or stops the rotation, thereby reducing the rotational lift. The control unit 63 increases the rotation speed of the rotor 13, thereby increasing the rotational lift. Since the thrust decreases when the rotation speed of the rotor 13 is reduced or stopped, the control unit 63 also takes the thrust into consideration and adjusts it so that the flight speed and flight altitude fall within the permissible range.

The control unit 63 adjusts the gliding lift provided by the fixed wing 12 by controlling the drive of the lift adjust mechanism 14. As an example, the control unit 63 in the present embodiment generates a control signal indicating a target tilt angle for each rotor 13 to achieve an instructed flight state. The control unit 63 outputs a control signal indicating a target tilt angle to a drive circuit (not shown) that drives an inverter of a tilt adjustment device. The drive circuit drives the motor of the tilt adjustment device via an inverter so that the tilt angle of the rotor 13 coincides with the target tilt angle.

The control unit 63 generates control signals indicating target positions for each of the flaps 142 to achieve the instructed flight state. The control unit 63 outputs a control signal indicating a target position to a drive circuit (not shown) that drives an inverter of a flap adjustment device. The drive circuit drives the motor of the flap adjustment device via an inverter so that the position of a flap 142 coincides with the target position.

The output unit 64 outputs a control signal generated by the control unit 63 to a control target. In the operation management system 40, the configuration of the monitoring device 50 is similar to that of the preceding embodiment (see FIG. 9). The control device 60 is functionally arranged in the ECU 20, for example, as in the preceding embodiment.

### <Control Method>

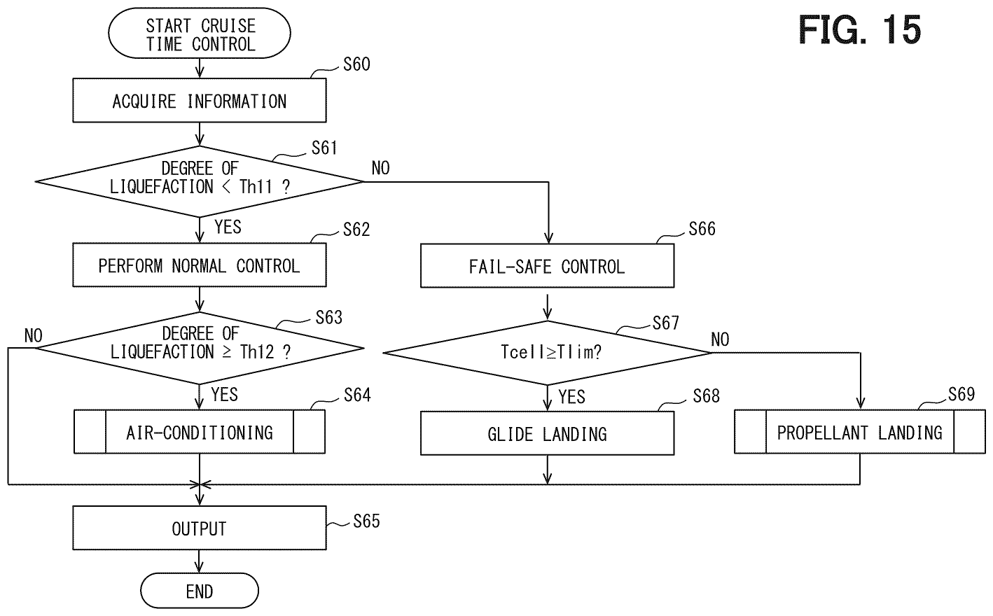

FIG. 15 shows an example of a control method. The execution of the processing of each functional block of the control device 60 by a processor 201 corresponds to performing a control method.

As an example, in the present embodiment, the control device 60 repeatedly performs the process shown in FIG. 15 during a cruise period P2. The control device 60 may repeatedly perform the process shown in FIG. 15 during the period from takeoff to landing.

As shown in FIG. 15, first, the control device 60 acquires information regarding a phase state of the latent heat storage material 152 (step S60). As an example, the acquisition unit 61 in the present embodiment acquires the phase state estimated by the monitoring device 50. The acquisition unit 61 also acquires other information, e.g., battery pack information, flight information, weather information, and regulation information.

Next, the control device 60 compares the degree of liquefaction, which is the acquired phase state, with a threshold value Th11, and determines whether the degree of liquefaction is less than the threshold value Th11 (step S61). The determination unit 62 of the control device 60 determines which control mode should be performed based on the degree of liquefaction. The threshold value Th11 is a predetermined degree of liquefaction, and is stored in advance in a storage medium. As an example, in the present embodiment, the predetermined degree of liquefaction is 100%.

For example, when acquiring the total phase state of the latent heat storage material, the determination unit 62 may make a YES determination in case that the total liquefaction degree of the latent heat storage material is less than the threshold value Th11, and may make a NO determination in case that the total liquefaction degree is equal to or greater than the threshold value Th11. For example, when acquiring the phase state for a unit of battery pack, the determination unit 62 may make a YES determination when the degree of liquefaction of at least one latent heat storage material 152 is less than the threshold value Th11, and may make a NO determination when the degree of liquefaction of all latent heat storage materials 152 is equal to or greater than the threshold value Th11. The determination unit 62 may make a NO determination when the number of latent heat storage materials 152 whose liquefaction degree is equal to or greater than the threshold value Th11 is greater than a predetermined number, and may otherwise make a YES determination. The predetermined number is set, for example, based on the minimum number of batteries 151 required to ensure lift and thrust for safe cruising.

When the degree of liquefaction is less than the threshold value Th11, the control device 60 performs normal control (step S62). The control unit 63 performs normal control when the latent heat storage material 152 is at least partially in a solid phase. In normal control, the control unit 63 performs control to realize an instructed flight state, e.g., control of the rotor 13, according to the operation plan. The control unit 63 performs control to maintain a cruise state.

Next, the control device 60 compares the degree of liquefaction with a threshold value Th12, and determines whether the degree of liquefaction is equal to or greater than the threshold value Th12 (step S63). The determination unit 62 determines whether or not to perform air-conditioning control based on the degree of liquefaction. The threshold value Th12 is a predetermined degree of liquefaction, and is stored in advance in a storage medium. As an example, in the present embodiment, the predetermined degree of liquefaction is 50%.

When the degree of liquefaction is equal to or greater than the threshold value Th12, the control device 60 performs air-conditioning control (step S64). When the degree of liquefaction is less than the threshold value Th12, that is, when the degree of liquefaction is low, the control device 60 performs an output process without performing air-conditioning control (step S65), and ends the series of processing. The output unit 64 of the control device 60 outputs a control signal for normal control.

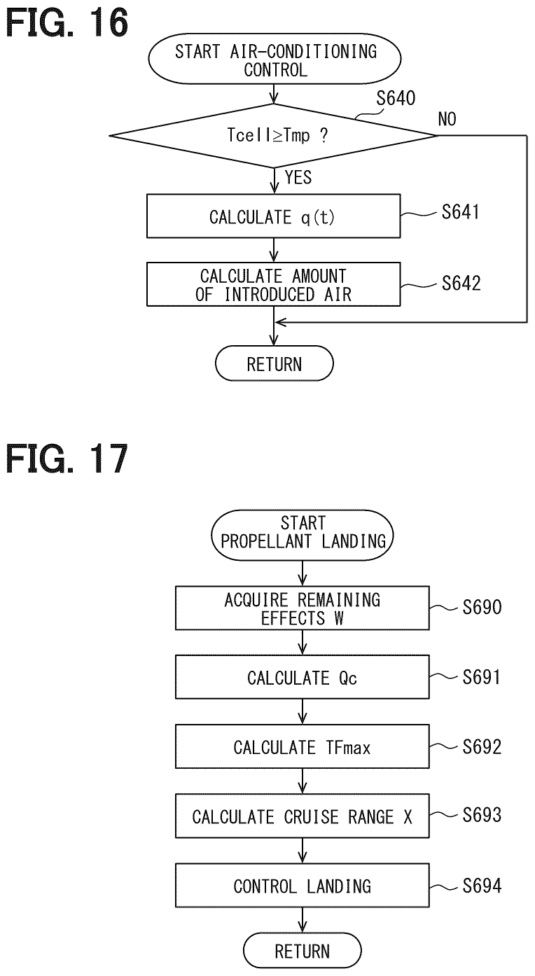

FIG. 16 shows processing of step S64, that is, an air-conditioning control. As shown in FIG. 16, first, the determination unit 62 of the control device 60 determines whether a battery temperature Tcell is equal to or higher than a melting point Tmp of the latent heat storage material 152 (step S640). The battery temperature Tcell is one of the pieces of battery pack information acquired by the acquisition unit 61. When the battery temperature Tcell is lower than the melting point Tmp, that is, when the battery temperature is low due to the cooling effect of the latent heat storage material 152, the air-conditioning control is not performed and the process proceeds to step S65.

When the battery temperature Tcell is equal to or higher than the melting point Tmp, the control device 60 calculates a heat generation amount q(t) of the battery 151 (step S641). The control unit 63 calculates the heat generation amount q(t), for example, by the method described in Equation 2. Next, the control device 60 calculates an amount of cool air to be introduced (step S642), and proceeds to step S65. The control unit 63 calculates the amount of cool air to be introduced from the air-conditioning device 18 to the battery pack 15 so that a heat dissipation amount Qw in the air is greater than the heat generation amount q(t). The control unit 63 may adjust the amount of cool air taken into the battery pack 15 by, for example, adjusting an opening degree of a valve in an air-conditioning pipe connecting the air-conditioning device 18 and the battery pack 15. The control unit 63 may adjust the amount and temperature of cool air taken into the battery pack 15 by controlling the operation of the air-conditioning device 18.

Although an example in which the determination process of step S640 is performed during air-conditioning control has been described, the present disclosure is not limited to such configuration. Before air-conditioning control is performed, a process of determining whether the battery temperature Tcell is equal to or higher than the melting point Tmp may be performed, and air-conditioning control may be performed when the battery temperature Tcell is equal to or higher than the melting point Tmp.

After performing the air-conditioning control, the control device 60 performs the process of step S65, that is, the output process, and ends the series of processes. The output unit 64 outputs a control signal for normal control and a control signal for air-conditioning control.

When the degree of liquefaction is equal to or greater than the threshold value Th11 in step S61, the control device 60 performs fail-safe control (step S66). In the fail-safe control, the control unit 63 reduces the output of the battery 151 compared to normal control, or stops the output of the battery 151. As an example, the control unit 63 in the present embodiment performs control for an emergency landing. The control unit 63 performs gliding landing control or propellant landing control depending on the battery temperature Tcell.

The determination unit 62 of the control device 60 determines whether the battery temperature Tcell is equal to or higher than a limit temperature Tlim (step S67). When the battery temperature Tcell is equal to or higher than the limit temperature Tlim, that is, when the battery temperature is high, the control device 60 performs gliding landing control (step S68). The control unit 63 reduces the output of the battery 151 compared to landing under normal control, or stops the output of the battery 151, so that the landing is mainly performed by gliding lift.

As an example, the control unit 63 in the present embodiment performs control so as to stop the output of all batteries 151. In other words, the aircraft is controlled to land by glider flight. After performing the gliding landing control, the control device 60 performs the output process of step S65, and ends the series of processes. The output unit 64 outputs a control signal for stopping the output of all batteries 151, that is, a control signal for stopping the drive of the motors of all EPUs 16. In such manner, the eVTOL 10 performs landing, for example, by gliding flight.

When the battery temperature Tcell is lower than the limit temperature Tlim, the control device 60 performs propellant landing control (step S69). FIG. 17 shows the process of step S69, that is, the propellant landing control. As shown in FIG. 17, first, the control device 60 acquires the remaining effect W (step S690). When the monitoring device 50 calculates the remaining effect W as a phase state, the control device 60 may acquire the remaining effect W from the monitoring device 50. The control device 60 may acquire the remaining effect W through calculations by the control unit 63. The remaining effect W[J] may be calculated, for example, using Equation 5 shown below. As stated above, m is a payload weight and c is a specific heat.

W=m·c·(Tlim−Tcell) (Equation 5)

Next, the control unit 63 calculates the heat generation amount Qc in case where cruising is continued (step S691). The control unit 63 calculates the heat generation amount Qc[W] based on, for example, Equation 6. As shown in Equation 6, the heat generation amount Qc can be expressed as a function of a sum of a headwind speed Vw and a flight speed V (cruise speed). Such a function may be set based on data from experiments or the like, or may be set based on the drag coefficient CD of the aircraft and the output characteristics of the EPU 16.

Qc=f(Vw+V) (Equation 6)

Next, the control unit 63 calculates a maximum flight time TFmax (step S692). The control unit 63 calculates the maximum flight time TFmax when flight is continued by the flight speed V, for example, based on Equation 7. The control unit 63 calculates the maximum flight time TFmax based on the remaining effect W and the heat generation amount Qc.

TFmax<W/Qc (Equation 7)

Next, the control unit 63 calculates a cruise range x (step S693). The control unit 63 calculates the cruise range x based on, for example, Equation 8. The control unit 63 calculates the cruise range x based on the flight speed V and the maximum flight time TFmax. A is a coefficient indicating a predetermined margin.

x<A·V·TFmax (Equation 8)

Next, the control unit 63 performs control so as to land within the cruise range x mainly by rotational lift (step S694). The control unit 63 reduces the output of the battery 151 compared to landing under normal control, or stops the output of the battery 151, so that the landing is performed mainly by rotational lift, that is, by the balance between rotational lift and gravity. The control unit 63 controls the drive of the rotor 13 and the like so that the eVTOL 10 moves primarily vertically downward. The landing of the eVTOL 10 has to have a component of vertical move at least, and may move diagonally downward, for example. The control unit 63 controls the output of the battery 151 so that the aircraft lands within the cruise range x.

After performing a vertical landing control, the control device 60 performs the process of step S65, that is, the output process, and ends the series of processes. The output unit 64 outputs the control signal generated in step S694 to the EPU 16.

### <Summary of Second Embodiment>

According to the control device 60 of the present embodiment, information regarding the phase state of the latent heat storage material 152 included in the battery pack 15 is acquired, and the output of the battery 151 is controlled based on the acquired phase state. In such manner, it is possible to grasp the cooling performance of the latent heat storage material 152 thereby appropriate control according to the phase state is performable. Accordingly, flight safety is improvable. For example, excessive temperature rise of the battery 151 during flight is suppressible.

As an example, the control device 60 of the present embodiment determines whether the degree of liquefaction, which is a phase state during flight, is less than the threshold value Th11 (predetermined value), and performs normal control when the degree of liquefaction is less than the threshold value Th11. On the other hand, when the degree of liquefaction is equal to or greater than the threshold value Th11, fail-safe control is performed so as to reduce the output of the battery 151 compared to normal control, or to stop the output of the battery 151. When the degree of liquefaction is high, the progress of liquefaction can be slowed or stopped by implementing fail-safe control. In such manner, safe landing is performable, for example.

As an example, the control device 60 of the present embodiment, when performing normal control, determines whether the degree of liquefaction is equal to or greater than the threshold value Th12 (second predetermined value) that is lower than the threshold value Th11 (first predetermined value), and when the degree of liquefaction is equal to or greater than the threshold value Th12, introduces cool air into the battery pack by the air-conditioning device 18. When normal control is performable but the degree of liquefaction is relatively high, the latent heat storage material 152 and the battery 151 can be cooled. In such manner, it is possible to suppress the progress of the degree of liquefaction or to reduce the degree of liquefaction. Therefore, normal control is made continuable, ultimately improving flight safety.

As an example, the control device 60 of the present embodiment controls the amount of cool air introduced into the battery pack 15 based on the output of the battery 151 during flight, e.g., based on the heat generation amount q(t). In such manner, by taking into consideration the heat generation amount q(t) of the battery 151, the battery 151 and the latent heat storage material 152 are efficiently coolable by air conditioning.

As an example, when performing fail-safe control, the control device 60 of the present embodiment calculates the cruise range x based on (i) the remaining effect W of the latent heat storage material 152, which is in a phase state, and (ii) the output of the battery 151, and performs control according to the cruise range x. In such manner, by knowing the cruise range x, evacuation (emergency landing) with safety in mind becomes possible, for example.

As an example, the control device 60 of the present embodiment determines whether the battery temperature Tcell is equal to or higher than the limit temperature Tlim of the battery when performing fail-safe control, and when the battery temperature Tcell is equal to or higher than the limit temperature Tlim, reduces the output of the battery 151 compared to normal control or stops the output of the battery 151 so that the landing is mainly performed by gliding lift. In such manner, it is possible to prevent the battery 151 from becoming overheated, thereby improving the safety of landing, for example.

The program (program 203P) of the present embodiment includes (a) causing at least one processor 201 (processing unit) to acquire the phase state of the latent heat storage material 152 provided in the battery pack 15, and (b) controlling the output of the battery 151 provided in the battery pack 15 based on the phase state. According to such a program, it is possible to grasp the phase state of the latent heat storage material 152, that is, the cooling performance, and then perform control appropriate to the phase state. Therefore, appropriate control leading to flight safety is performable. Accordingly, flight safety is improvable.

### <Modification>

Although the processes that the control device 60 performs during flight have been described above, the present disclosure is not limited thereto. The control device 60 may perform a predetermined process based on the phase state before flight.

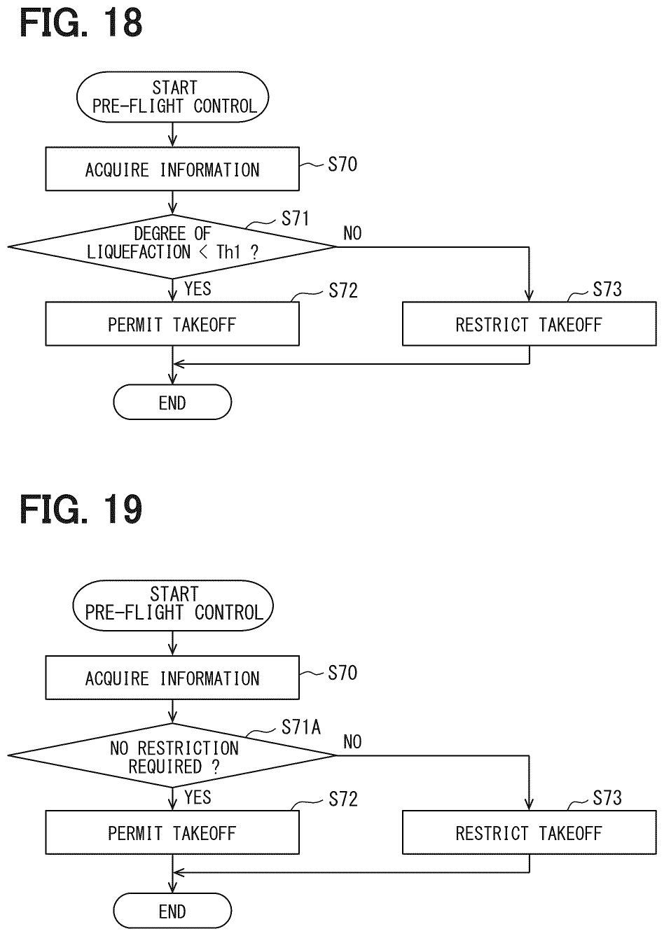

For example, in an example shown in FIG. 18, before takeoff, the acquisition unit 61 of the control device 60 acquires information about the battery pack 15 (step S70). The information includes information regarding the phase state of the latent heat storage material 152. Next, the determination unit 62 of the control device 60 determines whether the degree of liquefaction, which is the phase state, is less than a predetermined threshold value Th1 (step S71). When the degree of liquefaction is less than the threshold value Th1, the control device 60 permits the eVTOL 10 to take off (step S72), and ends the series of processes. When the degree of liquefaction is equal to or greater than the threshold value Th1, the control device 60 restricts the takeoff of the eVTOL 10 (step S73), and ends the series of processes. An example of a restriction is a prohibition of takeoff. According to the control method shown in FIG. 18, when the cooling performance of the latent heat storage material 152 is insufficient, takeoff is restricted, thereby making it possible to increase flight safety.

In a control method shown in FIG. 19, step S71 shown in FIG. 18 is replaced with a process of step S71A. The other processes are similar. In step S70, the control device 60 acquires, from the monitoring device 50, the result of the determination as to whether or not takeoff restriction is required. In the following step S71A, the control device 60 determines whether or not takeoff restriction is required based on the acquired information. When takeoff restriction is not required, the control device 60 performs the process of step S72, that is, permits the eVTOL 10 to take off. When takeoff restriction is required, the control device 60 performs the process of step S73, that is, restricts the takeoff of the eVTOL 10. In such manner, too, it is possible to achieve the same effect as the control method shown in FIG. 18.

The configuration described in the present embodiment is combinable with the configuration described in the preceding embodiment.

Although the combination of the monitoring device 50 and the control device 60 is shown, the present disclosure is not limited to such configuration. The control device 60 may be provided independently. For example, the control device 60 may have a function of estimating the phase state, and the acquisition unit 61 may acquire the estimation result. The phase state may be acquired from a functional unit other than the monitoring device 50.

### Other Embodiments

The present disclosure in the specification and drawings is not limited to the exemplified embodiments. The present disclosure includes embodiments described above and modifications of the above-described embodiments made by a person skilled in the art. For example, the disclosure is not limited to a combination of the components and/or elements described in the embodiments. The disclosure may be implemented in various combinations. The disclosure may have additional components that can be added to the embodiments. The disclosure may include modifications which have omission(s) of components/elements of the above-described embodiments. The disclosure may include replacements of components and/or elements between one embodiment and another embodiment, or combinations of components and/or elements between one embodiment and another embodiment. The technical scope disclosed in the present disclosure is not limited to the above-described embodiments. It should be understood that a part of disclosed technical scopes are indicated by claims, and the present disclosure further includes modifications within an equivalent scope of the claims.

The disclosure in the specification, drawings and the like is not limited by the description of the claims. The disclosure in the specification, drawings, and the like includes the technical ideas described in the claims, and further extend to a wider variety of technical ideas than those described in the claims. Therefore, various technical ideas can be extracted from the disclosure of the specification, drawings and the like without being limited to the description of the claims.

When it is mentioned that a certain element or layer is “on,” “coupled,” “connected,” or “bonded,” the certain element or layer may be directly on, coupled, connected, or bonded to another element or layer, or an interposed element or an interposed layer may be present. In contrast, when it is mentioned that a certain element is “directly on,” “directly coupled,” “directly connected,” or “directly bonded” to another element or layer, no interposed element or interposed layer is present. Other words used to describe a relationship between elements should be interpreted in the similar manner (for example, “between” and “directly between,” “adjacent to” and “directly adjacent to”). When used in the specification, the term “and/or” includes any of and all combinations related to one or multiple associated listed items.

Each of various flowcharts illustrated in the present disclosure is an example, and the number of steps constituting the flowchart and the execution order of the processes can be changed as appropriate. Further, the device, the system and the method therefor which have been described in the present disclosure may also be realized by a dedicated computer which implements a processor programmed to execute one or more functions using computer programs. The device and the method described in the present disclosure may also be realized by a dedicated hardware logic circuit. Further, the device, the system, and the method thereof described in the present disclosure may also be realized by one or more dedicated computers configured by a combination of a processor that performs a computer program and one or more hardware logic circuit.

For example, some or all of the functions provided by the processor 201 may be realized as hardware. An aspect in which a certain function is implemented as hardware includes an aspect in which one or multiple ICs and the like are used for such implementation. As the processor (arithmetic core), a CPU, an MPU, a GPU, a DFP, or the like can be adopted. The CPU is an abbreviation of a central processing unit. MPU is an abbreviation of Micro-Processing Unit. GPU is an abbreviation of Graphics Processing Unit. DFP is an abbreviation of Data Flow Processor.

A part or all of the functions of the processor 201 may be implemented by combining multiple types of arithmetic processing devices. A part or all of the functions of the processor 201 may be implemented using an SoC, an ASIC, an FPGA, or the like. SoC is an abbreviation of System on Chip. The ASIC is an abbreviation of an application specific integrated circuit. FPGA is an abbreviation of Field-Programmable Gate Array. The same applies to the processor 311.

Further, the computer program described above may be stored in a computer-readable, non-transitory, tangible storage medium as instructions to be executed by a computer. As the program storage medium, an HDD, an SSD, a flash memory, or the like can be adopted. HDD is an abbreviation of a hard disk drive. SSD is an abbreviation of Solid State Drive. A program for causing a computer to function as the monitoring device 50 or the control device 60, and a non-transitory tangible storage medium such as a semiconductor memory in which the program is recorded are also included in the scope of the present disclosure.

### Disclosure of Technical Ideas

The specification discloses multiple technical ideas described in multiple items listed below. Some items may be written in a multiple dependent form with subsequent items referring to the preceding item as an alternative. Further, some items may be written in a multiple dependent form referring to another multiple dependent form. These items described in such multiple dependent form define multiple technical ideas.

### <Technical Idea 1>

A monitoring device for monitoring a state of a battery pack (15) mounted on an electric flying object (10), the battery pack including a battery (151) and a latent heat storage material (152) that is capable of changing a phase state between a solid and a liquid, the monitoring device includes: an acquisition unit (51) configured to acquire information regarding the battery pack; an estimation unit (52) configured to estimate the phase state of the latent heat storage material based on the acquired information; and an output unit (53) configured to output information regarding the phase state.

### <Technical Idea 2>

In the monitoring device according to technical idea 1, the estimation unit is configured to calculate, based on the acquired information, a stored heat amount in the latent heat storage material before flight, and an integrated value of a heat generation amount generated by the battery during the flight, and estimate the phase state during the flight using the stored heat amount and the integrated value of the heat generation amount.

### <Technical Idea 3>

In the monitoring device according to technical idea 1 or technical idea 2, the estimation unit is configured to calculate a stored heat amount in the latent heat storage material before flight based on the acquired information, and to estimate the phase state before the flight using the stored heat amount.

### <Technical Idea 4>

In the monitoring device according to technical idea 1 or technical idea 2, the estimation unit estimates that the latent heat storage material is in a solid state when a temperature of the battery before flight is equal to or lower than a melting point of the latent heat storage material.

### <Technical Idea 5>

The monitoring device according to technical idea 3 or technical idea 4 further includes a determination unit (54) configured to determine whether it is necessary to restrict takeoff of the electric flying object based on the phase state. In this case, the output unit outputs a result of the determination.

### <Technical Idea 6>

In the monitoring device according to technical idea 1, the estimation unit estimates the phase state based on a predictive model generated by machine learning, as teacher data, using temperature drop information of the battery when transitioning from a takeoff period to a cruise period.

### <Technical Idea 7>

In the monitoring device according to technical idea 1, the estimation unit estimates the phase state based on a predictive model generated by machine learning, as teacher data, using a rate of a temperature rise of the battery relative to an integrated value of a heat generation amount of the battery.

### <Technical Idea 8>

A control device is for an electric flying object (10) that drives a drive target including a rotor (13) using a battery pack (15), and the battery pack includes a battery (151) and a latent heat storage material (152) that changes a phase state between a solid and a liquid. In this case, the control device includes: an acquisition unit (61) configured to acquire information regarding the phase state of the latent heat storage material; and a control unit (63) configured to control an output of the battery based on the phase state.

### <Technical Idea 9>

The control device according to technical idea 8 further includes: a determination unit (62) configured to determine whether a degree of liquefaction, which is the phase state, is less than a predetermined value during flight. In this case, the control unit is configured to perform a normal control when the degree of liquefaction is less than a predetermined value, and to perform a fail-safe control to reduce an output of the battery compared to the normal control or to stop the output of the battery when the degree of liquefaction is equal to or greater than the predetermined value.

### <Technical Idea 10>

In the control device according to technical idea 9, the predetermined value is a first predetermined value, the determination unit determines whether the degree of liquefaction is equal to or greater than a second predetermined value that is lower than the first predetermined value when performing the normal control, and the control unit performs a control operation in which cool air is introduced from an air-conditioning device (18) mounted on the electric flying object into the battery pack, when the degree of liquefaction is equal to or greater than the second predetermined value.

### <Technical Idea 11>

In the control device according to technical idea 10, the control unit controls an amount of cool air introduced into the battery pack based on the output of the battery during the flight.

### <Technical Idea 12>

In the control device according to any one of technical ideas 9 to 11, the control unit calculates a cruise range based on a remaining effect of the latent heat storage material of the phase state and the output of the battery when performing the fail-safe control, and performs a control in accordance with the cruise range.

### <Technical Idea 13>

In the control device according to any one of technical ideas 9 to 12, the electric flying object includes the rotor that generates rotational lift, a fixed wing (12) that generates gliding lift, and a lift adjustment mechanism (14) that adjusts the gliding lift; the determination unit is configured to determine whether a temperature of the battery is equal to or higher than a limit temperature of the battery when performing the fail-safe control; and the control unit reduces the output of the battery compared to the normal control, or stops the output of the battery, to land mainly by the gliding lift, when the temperature of the battery is equal to or higher than the limit temperature.

### <Technical Idea 14>

In the control device according to any one of technical ideas 8 to 13, the control unit restricts or permits takeoff based on the phase state before flight.

What is claimed is:

1. A monitoring device for monitoring a state of a battery pack mounted on an electric flying object, the battery pack including a battery and a latent heat storage material that is capable of changing a phase state between a solid and a liquid, the monitoring device comprising:
an acquisition unit configured to acquire information regarding the battery pack;
an estimation unit configured to estimate the phase state of the latent heat storage material based on the acquired information; and
an output unit configured to output information regarding the phase state.

2. The monitoring device according to claim 1, wherein
the estimation unit is configured to
calculate, based on the acquired information, a stored heat amount in the latent heat storage material before flight, and an integrated value of a heat generation amount generated by the battery during the flight, and
estimate the phase state during the flight using the stored heat amount and the integrated value of the heat generation amount.

3. The monitoring device according to claim 1, wherein
the estimation unit is configured to
calculate a stored heat amount in the latent heat storage material before flight based on the acquired information, and
estimate the phase state before the flight using the stored heat amount.

4. The monitoring device according to claim 1, wherein
the estimation unit estimates that the latent heat storage material is in a solid state when a temperature of the battery before flight is equal to or lower than a melting point of the latent heat storage material.

5. The monitoring device according to claim 3, further comprising:
a determination unit configured to determine whether it is necessary to restrict takeoff of the electric flying object based on the phase state, wherein
the output unit outputs a result of the determination.

6. The monitoring device according to claim 1, wherein
the estimation unit estimates the phase state based on a predictive model generated by machine learning, as teacher data, using temperature drop information of the battery when transitioning from a takeoff period to a cruise period.

7. The monitoring device according to claim 1, wherein
the estimation unit estimates the phase state based on a predictive model generated by machine learning, as teacher data, using a rate of a temperature rise of the battery relative to an integrated value of a heat generation amount of the battery.

8. A control device for an electric flying object that drives a drive target including a rotor using a battery pack, the battery pack including a battery and a latent heat storage material that changes a phase state between a solid and a liquid, the control device comprising:
an acquisition unit configured to acquire information regarding the phase state of the latent heat storage material; and
a control unit configured to control an output of the battery based on the phase state.

9. The control device according to claim 8, further comprising:
a determination unit configured to determine whether a degree of liquefaction, which is the phase state, is less than a predetermined value during flight, wherein
the control unit is configured to perform a normal control when the degree of liquefaction is less than a predetermined value, and to perform a fail-safe control to reduce an output of the battery compared to the normal control or to stop the output of the battery when the degree of liquefaction is equal to or greater than the predetermined value.

10. The control device according to claim 9, wherein
the predetermined value is a first predetermined value,
the determination unit determines whether the degree of liquefaction is equal to or greater than a second predetermined value that is lower than the first predetermined value when performing the normal control, and
the control unit performs a control operation in which cool air is introduced from an air-conditioning device mounted on the electric flying object into the battery pack, when the degree of liquefaction is equal to or greater than the second predetermined value.

11. The control device according to claim 10, wherein
the control unit controls an amount of cool air introduced into the battery pack based on the output of the battery during the flight.

12. The control device according to claim 9, wherein
the control unit calculates a cruise range based on a remaining effect of the latent heat storage material of the phase state and the output of the battery when performing the fail-safe control, and performs a control in accordance with the cruise range.

13. The control device according to claim 9, wherein
the electric flying object includes the rotor that generates rotational lift, a fixed wing that generates gliding lift, and a lift adjustment mechanism that adjusts the gliding lift,
the determination unit is configured to determine whether a temperature of the battery is equal to or higher than a limit temperature of the battery when performing the fail-safe control, and
the control unit reduces the output of the battery compared to the normal control, or stops the output of the battery, to land mainly by the gliding lift, when the temperature of the battery is equal to or higher than the limit temperature.

14. The control device according to claim 8, wherein
the control unit restricts or permits takeoff based on the phase state before flight.

15. An operation management system comprising:
a monitoring device configured to acquire information regarding a battery pack that is mounted on an electric flying object and to estimate a phase state of a latent heat storage material that is provided in the battery pack; and
a control device configured to control an output of a battery provided in the battery pack, based on the phase state of the latent heat storage material.

16. A non-transitory computer readable medium storing a computer program product includes instructions configured to, when executed by at least one processor, cause the at least one processor to:
acquire information regarding a battery pack; and
estimate a phase state of a latent heat storage material of the battery pack, based on the acquired information regarding the battery pack.

17. The non-transitory computer readable medium according to claim 16, wherein the instructions are configured to, when executed by the at least one the processor, further cause the at least one processor to
control an output of a battery in the battery pack based on the estimated phase state.
